(19) United States
(12) Patent Application Publication
(10) Pub. No.: US 2026/0038602 A1
(43) Pub. Date: Feb. 5, 2026

(54) MEMORY DEVICE DETECTING DATA RECOVER READ LEVEL USING CELL COUNT AND OPERATING METHOD THEREOF

(71) Applicant: SAMSUNG ELECTRONICS CO., LTD., Suwon-si (KR)

(72) Inventors: HYOJIN AHN, Suwon-si (KR); JEONGYEOL KIM, Suwon-si (KR); HOON JO, Suwon-si (KR)

(73) Assignee: SAMSUNG ELECTRONICS CO., LTD., Suwon-si (KR)

(21) Appl. No.: 19/194,971

(22) Filed: Apr. 30, 2025

(30) Foreign Application Priority Data
Aug. 2, 2024 (KR) 10-2024-0102876

(51) Int. Cl. G11C 16/26; G11C 16/04

(52) U.S. Cl. CPC G11C 16/26; G11C 16/0483

(57) ABSTRACT

There is provided a memory device including a memory cell array having a plurality of memory cells connected to a plurality of word lines, and control logic. The control logic groups adjacent memory cells, among the plurality of memory cells, connected to an adjacent word line adjacent to a selection word line, among the plurality of word lines, into a plurality of aggressor cell groups, identifies one or more coupling patterns of selection memory cells connected to the selection word line based on each of the plurality of aggressor cell groups, counts a number of first memory cells in a first area of neighboring first and second states corresponding to a first coupling pattern, among the one or more coupling patterns, and obtains an offset level for a data recovery read operation of the first and second states based on the number of first memory cells.

### CROSS-REFERENCE TO RELATED APPLICATIONS

This application is based on and claims priority under 35 U.S.C. § 119 to Korean Patent Application No. 10-2024-0102876 filed on Aug. 2, 2024, in the Korean Intellectual Property Office, the disclosures of which are incorporated by reference herein in their entireties.

### BACKGROUND

Example embodiments of the present disclosure relate to a semiconductor memory device, and more specifically, to a memory device performing data recovery read operation using a cell count value and an operating method of the memory device.

Semiconductor memories may be classified as a volatile memory or a non-volatile memory. Typically, volatile memories (e.g., a dynamic random access memory (DRAM) or a static random access memory (SRAM)) may exhibit faster read and/or write speeds when compared to the non-volatile memory. However, data stored in the volatile memory may disappear when power applied to the volatile memory is turned off. In contrast, the non-volatile memory may retain the data even when the power is turned off. A representative example of a non-volatile memory device is flash memory.

Recently, a technology for stacking memory cells in three dimensions, such as vertical flash memory devices (VNAND), has been actively researched to improve integration. As the vertical flash memory devices are being developed, the number of word lines stacked vertically is increasing. The number of string selection lines formed on the top gate layer is also increasing.

The threshold voltage distributions of memory cells connected to the selection word line of the flash memory device may be distorted by word line coupling of adjacent memory cells. In addition, during the retention period, the degree of charge loss of the selection memory cells due to the influence of the states of the adjacent memory cells may vary, and the degree to which the threshold voltage distribution of each selection memory cell widens may be greater. The flash memory device may perform a data recovery read operation to reduce the threshold voltage distortion of the selection memory cells.

### SUMMARY

Example embodiments of the present disclosure provide a memory device that performs a data recovery read operation using the cell count of a specific area of a threshold voltage distribution.

According to an aspect of the disclosure, there is provided a memory device including: a memory cell array including a plurality of memory cells connected to a plurality of word lines; and a control logic configured to: group adjacent memory cells, among the plurality of memory cells, connected to an adjacent word line adjacent to a selection word line, among the plurality of word lines, into a plurality of aggressor cell groups, identify one or more coupling patterns of selection memory cells connected to the selection word line based on each of the plurality of aggressor cell groups, count a number of first memory cells in a first area of neighboring first and second states corresponding to a first coupling pattern, among the one or more coupling patterns, and obtain an offset level for a data recovery read operation of the first and second states based on the number of first memory cells.

According to an aspect of the disclosure, there is provided a storage device including: a memory device including a memory cell array having a plurality of memory cells connected to a plurality of word lines, and a peripheral circuit configured to control the memory cell array; and a memory controller configured to: group adjacent memory cells, among the plurality of memory cells, connected to an adjacent word line adjacent to a selection word line, among the plurality of word lines into a plurality of aggressor cell groups, identify one or more coupling patterns of selection memory cells connected to the selection word line based on each of the plurality of aggressor cell groups, count a number of first memory cells in a first area of neighboring first and second states corresponding to a first coupling pattern, among the one or more coupling patterns, and obtain an offset level for a data recovery read operation of the first and second states based on the number of first memory cells.

According to an aspect of the disclosure, there is provided a data recovery read method of a storage device which includes a memory device having a plurality of memory cells connected to a plurality of word lines and a memory controller for controlling the memory device, the data recovery read method including: grouping adjacent memory cells, among the plurality of memory cells, connected to an adjacent word line adjacent to a selection word line, among the plurality of word lines, into a plurality of aggressor cell groups; identifying one or more coupling patterns of selection memory cells connected to the selection word line based on each of the plurality of aggressor cell groups; counting a number of first memory cells in a first area of neighboring first and second states corresponding to a first coupling pattern, among the one or more coupling patterns; and obtaining an offset level for a data recovery read operation of the first and second states based on the number of first memory cells.

### BRIEF DESCRIPTION OF DRAWINGS

The above and other objects and features of the present disclosure will become apparent by describing in detail embodiments thereof with reference to the accompanying drawings.

FIG. 1 is a block diagram illustrating an example embodiment of a storage device according to the present disclosure.

FIG. 2 is a block diagram illustrating as an example embodiment of the memory device illustrated in FIG. 1.

FIG. 3 is a circuit diagram illustrating an example embodiment of a memory block BLK1 of the memory cell array illustrated in FIG. 2.

FIG. 4 is a circuit diagram illustrating cell strings selected by the first string selection line SSL1 from among the cell strings of the memory block BLK1 illustrated in FIG. 3.

FIGS. 5A, 5B and 5C are diagrams illustrating an example embodiment of threshold voltage distributions of memory cells illustrated in FIG. 4.

FIG. 6 is a diagram illustrating a method for reducing word line coupling of the memory device illustrated in FIG. 2 according to an example embodiment.

FIG. 7 is a diagram illustrating threshold voltage distributions associated with memory cells of an k-th word line before and after word line coupling caused when memory cells of an (k+1)-th word line are programmed.

FIG. 8 is a diagram illustrating all threshold voltage distributions corresponding to memory cells experiencing the coupling and memory cells not experiencing the coupling.

FIG. 9 is a graph illustrating states in which a plurality of memory cells are degraded, according to an embodiment.

FIG. 10 is a diagram illustrating a coupling pattern and an aggressor cell group, according to an embodiment.

FIG. 11 is a graph illustrating a method of grouping a plurality of aggressor cell groups, according to an embodiment.

FIG. 12 is a graph illustrating sub-threshold voltage distributions based on the plurality of aggressor cell groups, according to an embodiment.

FIGS. 13 and 14 are graphs illustrating sub-read voltage sets for the sub-threshold voltage distributions of FIG. 12, according to an embodiment.

FIGS. 15A and 15B are diagrams illustrating a read operation using the sub-read voltage set shown in FIG. 13.

FIGS. 16A and 16B are diagrams illustrating a read operation using the sub-read voltage set shown in FIG. 14.

FIG. 17 is a graph illustrating a valley search operation and a method of obtaining a plurality of points, according to an embodiment.

FIG. 18 is a graph illustrating a method of obtaining a first voltage level in a first function, according to an embodiment.

FIG. 19 is a graph illustrating a method of obtaining a second voltage level in a second function, according to an embodiment.

FIG. 20 is a graph illustrating a method of obtaining sub-read voltage sets, according to an embodiment.

FIG. 21 is a graph illustrating a method of grouping a plurality of aggressor cell groups, according to an embodiment.

FIG. 22 is a graph illustrating sub-threshold voltage distributions, according to the plurality of aggressor cell groups, according to an embodiment.

FIG. 23 are a graph illustrating sub-read voltage sets for the sub-threshold voltage distributions of FIG. 22, according to an embodiment.

FIG. 24 is a table illustrating sub-read voltage sets for a triple level cell (TLC), according to an embodiment.

FIG. 25 is a graph illustrating the results of measuring the correlation between the cell count value of a specific area X of the distribution and the offset level.

FIG. 26 is a table illustrating an example embodiment of cell count values and offset levels of the first to fourth aggressor cell groups.

FIG. 27 is a diagram illustrating an example embodiment of a method of mathematically calculating the offset level using the cell count values of the first to fourth aggressor cell groups.

FIG. 28 is a graph illustrating offset levels for each state of selection memory cells that have been degraded by the first to fourth aggressor cell groups.

FIGS. 29A, 20B and 29C illustrate graphs of threshold voltage distributions of selection memory cells coupled to adjacent word lines, according to an embodiment.

FIG. 30 is a flowchart for explaining a data read operation method of a storage device according to embodiments of the present disclosure.

FIG. 31 is a flowchart of a data recovery read operation method, according to an embodiment.

FIG. 32 is a diagram illustrating an example embodiment of a memory device having a multi-stack structure.

FIG. 33 is a block diagram illustrating an example in which a storage device according to an embodiment of the present disclosure is implemented with a solid state drive (SSD).

### DETAILED DESCRIPTION

Below, example embodiments of the present disclosure will be described in detail and clearly to such an extent that an ordinary one in the art easily implements the inventive concepts.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

The embodiments of the disclosure are example embodiments, and thus, the disclosure is not limited thereto, and may be realized in various other forms. As is traditional in the field, embodiments may be described and illustrated in terms of blocks, as shown in the drawings, which carry out a described function or functions. These blocks, which may be referred to herein as units or modules or the like, or by names such as device, logic, circuit, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

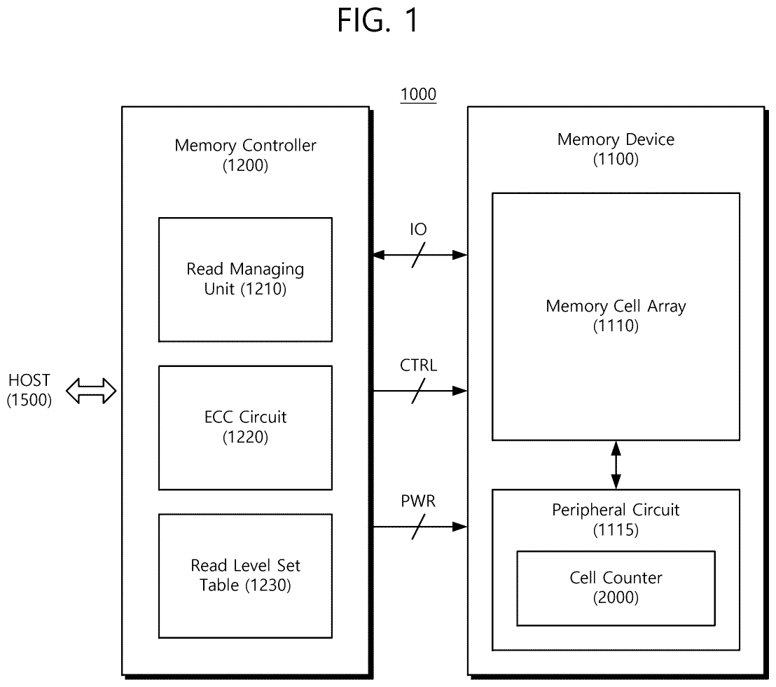

FIG. 1 is a block diagram illustrating an example embodiment of a storage device according to the present disclosure.

Referring to FIG. 1, the storage device 1000 may include a memory device 1100 and a memory controller 1200. The storage device 1000 may be a flash storage device based on a flash memory. For example, the storage device 1000 may be implemented as a solid-state drive (SSD), a universal flash storage (UFS), a memory card, or the like.

The storage device 1000 may communicate with the host 1500 through a host interface. The storage device 1000 may receive a write request to store data in the memory device 1100 or a read request to read data stored in the memory device 1100 from the host 1500. The storage device 1000 may receive a logical address for identifying data from the host 1500.

The memory device 1100 may receive input/output signals IO from the memory controller 1200 through input/output lines, receive control signals CTRL through control lines, and receive external power supply PWR through power lines. The storage device 1000 may store data in the memory device 1100 under the control of the memory controller 1200.

The memory device 1100 may include a memory cell array 1110 and a peripheral circuit 1115. The memory cell array 1110 may have a vertical 3D structure. The memory cell array 1110 may include a plurality of memory cells. Multi-bit data may be stored in each memory cell.

The memory cell array 1110 may be located (e.g., provided) next to or above the peripheral circuit 1115 in terms of the design layout structure. A structure in which the memory cell array 1110 is positioned over the peripheral circuit 1115 may be referred to as a cell on peripheral (COP) structure.

The memory cell array 1110 may be manufactured as a chip separate from the peripheral circuit 1115. An upper chip including the memory cell array 1110 and a lower chip including the peripheral circuit 1115 may be connected to each other by a bonding method. Such a structure may be referred to as a chip-to-chip (C2C) structure.

The peripheral circuit 1115 may include analog circuits and/or digital circuits required to store data in the memory cell array 1110 or read data stored in the memory cell array 1110. The peripheral circuit 1115 may receive the external power PWR through power lines and generate internal powers of various levels.

The peripheral circuit 1115 may receive commands, addresses, and/or data from the memory controller 1200 through input/output lines. The peripheral circuit 1115 may store data in the memory cell array 1110 according to the control signals CTRL. However, the disclosure is not limited thereto, and as such, according to another embodiment, the peripheral circuit 1115 may read data stored in the memory cell array 1110 and provide the read data to the memory controller 1200.

The peripheral circuit 1115 may include a cell counter 2000. The cell counter 2000 may count the number of memory cells existing in a specific area of neighboring program states. The peripheral circuit 1115 may obtain an offset level for a data recovery read operation of neighboring program states based on the number of counted memory cells. The peripheral circuit 1115 may obtain a voltage level for a data recovery read operation of neighboring program states using the offset level.

The memory controller 1200 may include a read managing unit 1210, an ECC circuit 1220, and a read level set table 1230. The read managing unit 1210 may manage and control read voltages for reading data stored in the memory device 1100. The ECC circuit 1220 may detect and correct errors in data read from the memory device 1100. The read level set table 1230 may store the history of previous read voltages.

The read managing unit 1210 may manage a plurality of read voltages used in the memory device 1100 when data read from the memory device 1100 is not corrected by the ECC circuit 1220. For example, the read managing unit 1210 may manage a plurality of read voltages based on the read level set table 1230. The read managing unit 1210 may read data stored in the memory device 1100 at least twice and manage a plurality of read voltages based on the read data.

The ECC circuit 1220 may generate an error correction code for data to be stored in the memory device 1100. The generated error correction code may be stored in the memory device 1100 together with the data. Thereafter, the ECC circuit 1220 may detect and correct errors in the data read from the memory device 1100 based on the stored error correction code.

The ECC circuit 1220 may have a predetermined error correction capability. Data including error bits (or fail bits) exceeding the error correction capability of the ECC circuit 1220 is called ‘UECC (Uncorrectable ECC) data’. In an example case in which the data read from the memory device 1100 is UECC data, the read managing unit 1210 may perform a read operation again by managing a plurality of read voltages.

The read level set table 1230 may include information on read voltages read-passed in a previous read operation. A read-pass refers to a case where the data read by specific read voltages is normal data that does not include an error or a case where the included error may be corrected by the ECC circuit 1220.

For example, the read managing unit 1210 may manage a plurality of read voltages based on the read level set table 1230. That is, since the read voltages are adjusted based on previously read-passed read voltages and data is read using the adjusted read levels, the possibility that errors in the read data will be corrected by the ECC circuit 1220 may increase. That is, since the probability of a read pass is increased, the performance of the storage device 1000 may be improved.

The previously read-passed read voltages stored and managed in the read level set table 1230 are called ‘history read voltages’. The read level set table 1230 may include information on history read voltages for each of a plurality of pages included in the memory device 1100. For example, the read level set table 1230 may include information on previously read-passed read voltages for each word line.

The read voltage set table 1230 may store read voltages obtain by the read managing unit 1210. In some embodiments, the read voltage set table 1230 may store the default read voltage set, the optimum read voltage set, and/or the history read voltage set. In an embodiment, the read voltage set table 1230 may store read voltages to be used for the data recovery read operation.

The read managing unit 1210 may update the read level set table 1230. For example, the read managing unit 1210 may detect an optimal read voltage. The optimal read voltage may be a read voltage having the highest read pass probability when reading data. For example, the read managing unit 1210 may read data from the memory device 1100 at least twice and detect an optimal read voltage based on the read data. The operation of detecting the optimal read voltage is called a valley search.

The storage device 1000 may perform a valley search in an example case in which data stored in the memory device 1100 is determined to be UECC data. The memory device 1100 may detect an aggressor address after sensing a selection word line and compensate for threshold voltage information of the selection word line based on the detection result.

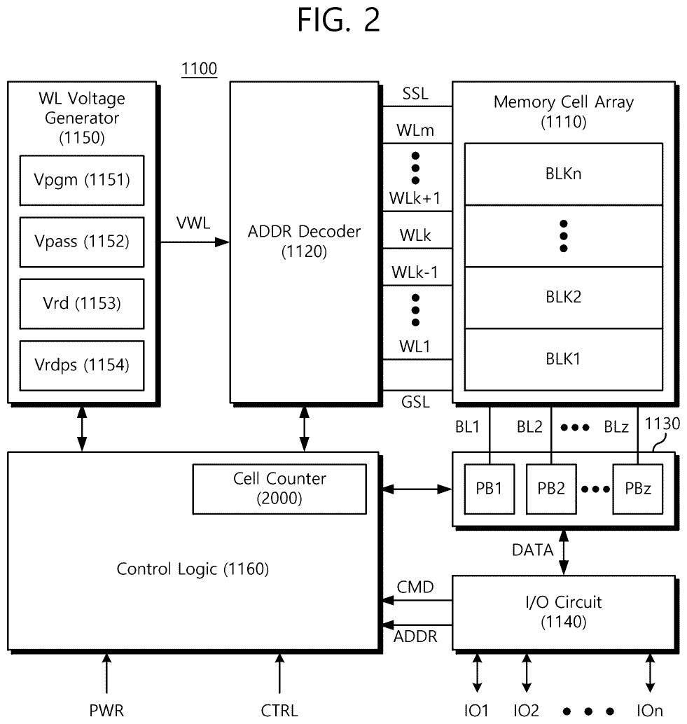

FIG. 2 is a block diagram illustrating as an example embodiment of the memory device illustrated in FIG. 1. Referring to FIG. 2, the memory device 1100 may include the memory cell array 1110 and the peripheral circuit 1115 (see FIG. 1). The peripheral circuit 1115 may include an address decoder 1120, a page buffer circuit 1130, a data input/output circuit 1140, a word line voltage generator 1150, and a control logic 1160.

The memory cell array 1110 may include a plurality of memory blocks BLK1 to BLKn. Each memory block may include a plurality of pages. Each page may include a plurality of memory cells. Each memory cell may store multi-bit data (e.g., two or more bits). Each memory block may correspond to an erase unit, and each page may correspond to a read unit and/or a write unit.

The memory cell array 1110 may be formed in a direction perpendicular to a substrate. A gate electrode layer and an insulation layer may be alternately deposited on the substrate. Each memory block (e.g., BLK1) may be connected to one or more string selection lines SSL, a plurality of word lines WL1 to WLm, and one or more ground selection lines GSL. WLk is a selection word line sWL and the remaining word lines (WL1 to WLk−1, WLk+1 to WLm) are unselection word lines uWL.

The address decoder 1120 may be connected to the memory cell array 1110 through selection lines SSL and GSL and word lines WL1 to WLm. The address decoder 1120 may select a word line during a program or read operation. The address decoder 1120 may receive the word line voltage VWL from the word line voltage generator 1150 and provide a program voltage or read voltage to the selection word line.

The page buffer circuit 1130 may be connected to the memory cell array 1110 through bit lines BL1 to BLz. Here, z is an integer. The page buffer circuit 1130 may temporarily store data to be stored in the memory cell array 1110 or data read from the memory cell array 1110. The page buffer circuit 1130 may include page buffers PB1 to PBz connected to respective bit lines. Each page buffer may include a plurality of latches to store or read multi-bit data.

The input/output circuit 1140 may be internally connected to the page buffer circuit 1130 through data lines and externally connected to the memory controller 1200 (refer to FIG. 1) through the input/output lines IO1 to IOn. Here, n is an integer. The input/output circuit 1140 may receive program data from the memory controller 1200 during a program operation. Also, the input/output circuit 1140 may provide data read from the memory cell array 1110 to the memory controller 1200 during a read operation.

The word line voltage generator 1150 may receive internal power from the control logic 1160 and generate a word line voltage VWL required to read or write data. The word line voltage VWL may be provided to a selection word line sWL or unselection word lines uWL through the address decoder 1120.

The word line voltage generator 1150 may include a program voltage generator 1151 and a pass voltage generator 1152. The program voltage generator 1151 may generate a program voltage Vpgm provided to the selection word line sWL during a program operation. The pass voltage generator 1152 may generate a pass voltage Vpass provided to the selection word line sWL and the unselection word lines uWL.

The word line voltage generator 1150 may include a read voltage generator 1153 and a read pass voltage generator 1154. The read voltage generator 1153 may generate a select read voltage Vrd provided to the select word line sWL during a read operation. The read pass voltage generator 1154 may generate a read pass voltage Vrdps provided to unselection word lines uWL. The read pass voltage Vrdps may be a voltage sufficient to turn on memory cells connected to the unselection word lines uWL during a read operation.

The control logic 1160 may control operations such as read, write, and erase of the memory device 1100 using commands CMD, addresses ADDR, and control signals CTRL provided from the memory controller 1200. The addresses ADDR may include a block selection address for selecting one memory block, a row address for selecting one page, and a column address for selecting one memory cell.

The control logic 1160 may include a cell counter 2000. The control logic 1160 may group adjacent memory cells connected to an adjacent word line adjacent to a selection word line of the memory device 1100 into a plurality of aggressor cell groups during a data recovery read operation. The control logic 1160 may classify coupling patterns of selection memory cells connected to the selection word line according to each aggressor cell group. The cell counter 2000 may count the number of memory cells existing in a specific area of neighboring first and second program states of any one of the coupling patterns.

The control logic 1160 may obtain an offset level for a data recovery read operation of the first and second states based on the number of counted memory cells. The control logic 1160 may obtain a voltage level for a data recovery read operation of the first and second program states using the offset level.

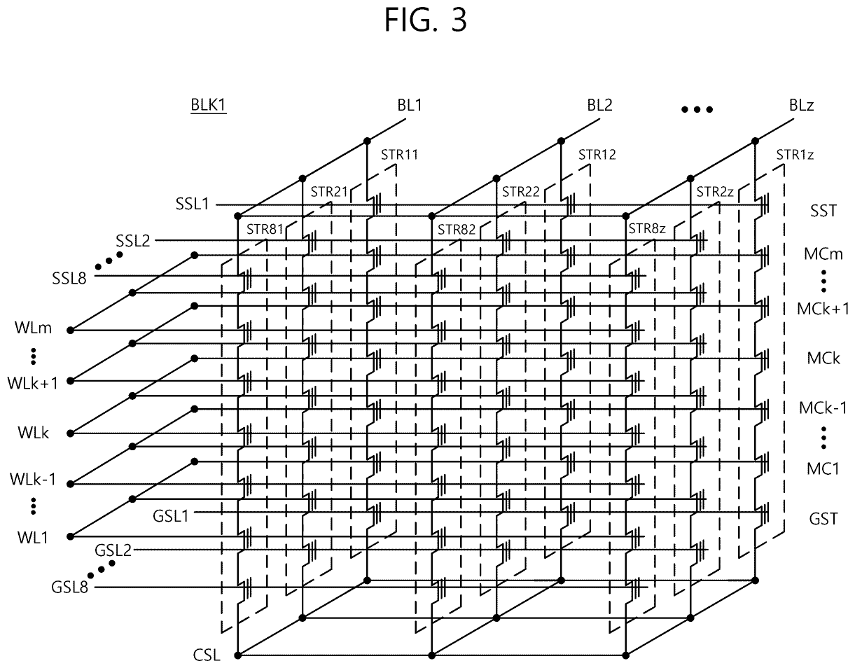

FIG. 3 is a circuit diagram illustrating an example embodiment of a memory block BLK1 of the memory cell array illustrated in FIG. 2.

Referring to FIG. 3, in the memory block BLK1, a plurality of cell strings STR11 to STR8z may be formed between the bit lines BL1 to BLz and a common source line CSL. Here, STR11 to STR8z may include STR11 to STR1z, STR21 to STR2z, . . . , and STR81 to STR8z. Each cell string includes a string selection transistor SST, a plurality of memory cells MC1 to MCm, and a ground selection transistor GST.

The string selection transistors SST may be connected with string selection lines SSL1 to SSL8. The ground selection transistors GST may be connected with ground selection lines GSL1 to GSL8. The string selection transistors SST may be connected with the bit lines BL1 to BLz, and the ground selection transistors GST may be connected with the common source line CSL.

The first to m-th word lines WL1 to WLm may be connected with the plurality of memory cells MC1 to MCm in a row direction. Here, m is an integer. The first to z-th bit lines BL1 to BLz may be connected with the plurality of memory cells MC1 to MCm in a column direction. First to z-th page buffers PB1 to PBz may be connected with the first to z-th bit lines BL1 to BLz.

The first word line WL1 may be placed above the first to eighth ground selection lines GSL1 to GSL8. The first memory cells MC1 that are placed at the same height from the substrate may be connected with the first word line WL1. The m-th word line WLm may be located below the first to eighth string selection lines SSL1 to SSL8. The m-th memory cells MCm located at the same height from the substrate may be connected to the m-th word line WLm. In a similar manner, the second to (m−1)-th memory cells MC2 to MCm−1 that are placed at the same heights from the substrate may be respectively connected with the second to (m−1)-th word lines WL2 to WLm−1, respectively.

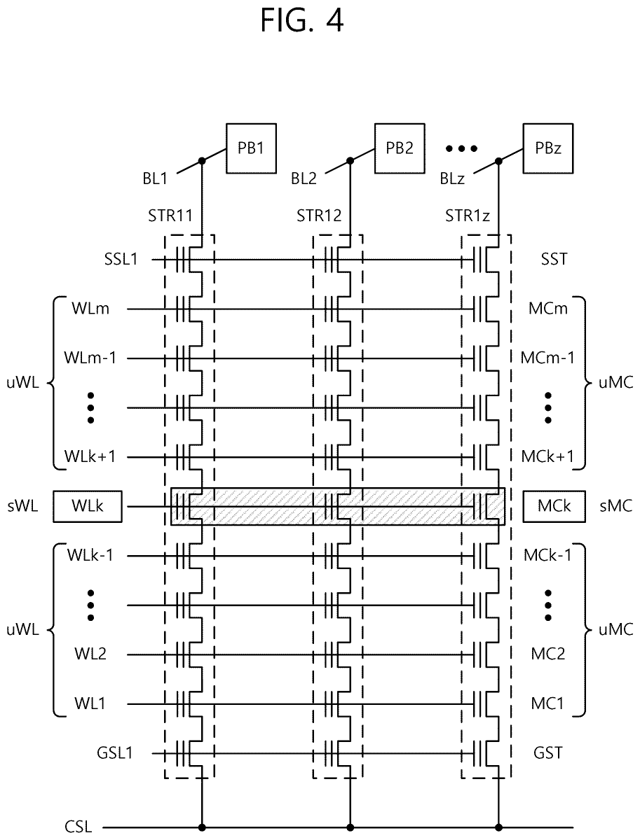

FIG. 4 is a circuit diagram illustrating cell strings selected by the first string selection line SSL1 from among the cell strings of the memory block BLK1 illustrated in FIG. 3.

The cell strings STR11 to STR1z may be selected by the first string selection line SSL1. The cell strings STR11 to STR1z may be connected to the first to z-th bit lines BL1 to BLz, respectively. The first to z-th page buffers PB1 to PBz may be connected to the first to z-th bit lines BL1 to BLz, respectively.

The cell string STR11 may be connected to the first bit line BL1 and the common source line CSL. The cell string STR11 may include string selection transistors SST selected by the first string selection line SSL1, first to m-th memory cells MC1 to MCm connected to the first to m-th word lines WL1 to WLm, and ground selection transistors GST selected by the first ground selection line GSL1. The cell string STR12 may be connected to the second bit line BL2 and the common source line CSL. The cell string STR1z may be connected to the z-th bit line BLz and the common source line CSL.

The first word line WL1 and the m-th word line WLm may be edge word lines (edge WL). The second word line WL2 and the (m−1)-th word line WLm−1 may be edge adjacent word lines. That is, the second word line WL2 and the (m−1)-th word line WLm−1 are word lines that are adjacent to an edge word line. The k-th word line WLk may be a selection word line sWL. The (k−1)-th word line WLk−1 and the (k+1)-th word line WLk+1 may be adjacent word lines adjacent to the selection word line. In an example case in which the k-th word line WLk is the selection word line sWL, the remaining word lines WL1 to WLk−1 and WLk+1 to WLm may be unselection word lines uWL.

The first memory cells MC1 and the m-th memory cells MCm may be edge memory cells. The second memory cells MC2 and the (m−1)-th memory cells MCm−1 may be edge adjacent memory cells. The k-th memory cells MCK may be selection memory cells sMC. The (k−1)-th memory cells MCk−1 and the (k+1)-th memory cells MCk+1 may be memory cells adjacent to the selection memory cells (adjacent MC). In an example case in which the k-th memory cells MCK are selection memory cells sMC, the remaining memory cells MC1 to MCk−1 and MCk+1 to MCm may be unselection memory cells uMC.

A set of memory cells selected by one string selection line and connected to one word line may be one page. For example, memory cells selected by the first string selection line SSL1 and connected to the k-th word line WLk may be one page. For example, eight pages may be configured on the k-th word line WLk. Among the eight pages, a page connected to the first string selection line SSL1 is a selected page, and pages connected to the second to eighth string selection lines SSL2 to SSL8 are unselected pages.

The first word line WL1 is a first edge word line (Edge1 WL), and the second word line WL2 is a first edge adjacent word line (Edge1 adjacent WL). The m-th word line WLm is the second edge word line (Edge2 WL), and the (m−1)-th word line WLm−1 is the second edge adjacent word line (Edge2 adjacent WL). And word lines between the first and second edge adjacent word lines are middle word lines. For example, the k-th word line WLk (k=3 to m−2) between the second word line WL2 and the (m−1)-th word line WLm−1 is a middle word line.

In the read operation, in an example case in which the second word line WL2 is the selection word line sWL, the remaining word lines may be unselection word lines uWL. The second word line WL2 may be a first edge adjacent word line (Edge1 adjacent WL). The second memory cells MC2 may be selection memory cells sMC. The remaining memory cells may be unselection memory cells uMC.

In an example case in which the (m−1)-th word line WLm−1 is the selection word line sWL, the remaining word lines may be unselection word lines uWL. The (m−1)-th word line WLm−1 may be a second edge adjacent word line. The (m−1)-th memory cells MCm−1 may be selection memory cells sMC. The remaining memory cells may be unselection memory cells uMC.

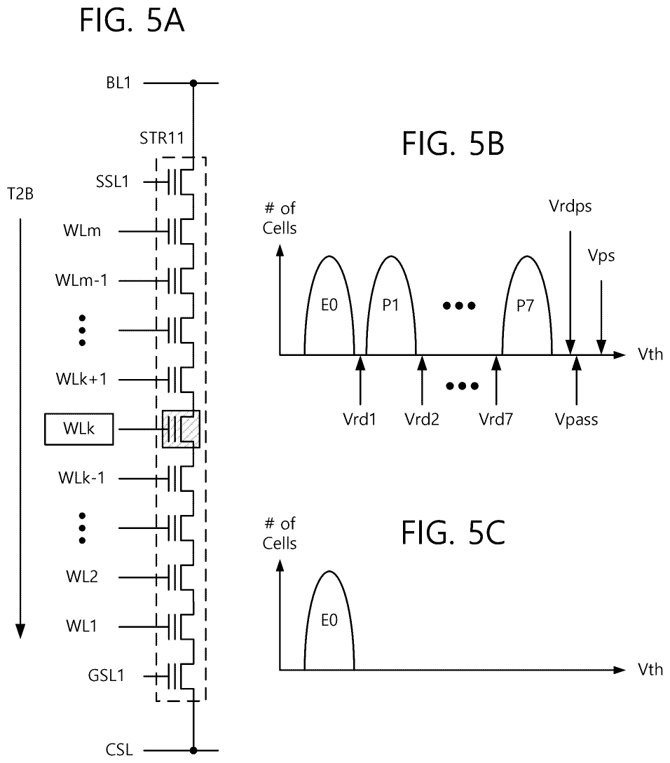

FIGS. 5A, 5B and 5C are diagrams illustrating an example embodiment of threshold voltage distributions of memory cells illustrated in FIG. 4.

In the diagrams illustrated in FIGS. 5B and 5C, the horizontal axis represents the threshold voltage Vth, and the vertical axis represents the number of memory cells. According to an embodiment, 3-bit data may be stored in one memory cell. A 3-bit memory cell may have one of eight states (E0, P1 to P7) according to the threshold voltage distribution. E0 represents an erase state, and P1 to P7 represent program states. However, the disclosure is not limited thereto, and as such, according to another embodiment, a number of bits of the data stored in the memory cell may be different than 3-bit data and a number of states according to the threshold voltage distribution different than eight.

During a read operation, the selection read voltages Vrd1 to Vrd7 may be provided to the selection word line sWL, and the pass voltage Vps and/or the read pass voltage Vrdps may be provided to the unselection word lines uWL as illustrated in FIG. 5B. The pass voltage Vps and/or the read pass voltage Vrdps may be a voltage sufficient to turn on the memory cells. For example, the pass voltage Vps may be provided to the adjacent word lines WLk+1, and the read pass voltage Vrdps may be provided to the unselection word lines other than the adjacent word lines.

The first selection read voltage Vrd1 may be a voltage level between the erase state E0 and the first program state P1. The second selection read voltage Vrd2 may be a voltage level between the first and second program states P1 and P2. In this way, the seventh selection read voltage Vrd7 may be a voltage level between the sixth and seventh program states P6 and P7.

In an example case in which the first selection read voltage Vrd1 is applied, the memory cell in the erase state E0 may be an on cell and the memory cell in the first to seventh program states P1 to P7 may be an off cell as illustrated in FIG. 5C. In an example case in which the second selection read voltage Vrd2 is applied, the memory cell in the erase state E0 and the first program state P1 may an on cell, and the memory cell in the second to seventh program states P2 to P7 may an off cell. In this way, in an example case in which the seventh selection read voltage Vrd7 is applied, the memory cell in the erase state E0 and the first to sixth program states P1 to P6 may be an on cell and the memory cell in the seventh program state P7 may be an off cell.

During a read operation, the k-th word line WLk may be selected. A power supply voltage may be applied to the string selection line SSL1 and the ground selection line GSL1, and the string select transistor SST and the ground select transistor GST may be turned on. Also, the selection read voltage Vrd may be provided to the selection word line sWL, and the read pass voltage Vrdps and/or the pass voltage Vps may be provided to the unselection word lines uWL.

In an example case in which the read operation of the k-th word line WLk is repeatedly performed, the high voltage read pass voltage Vrdps may be repeatedly provided to the remaining word lines. At this time, a read disturbance may occur in the remaining word lines, and thus the threshold voltage may be distorted. Memory cells connected to the k-th word line WLk may be off cells when a selection read voltage is provided. That is, in an example case in which the threshold voltage of the k-th memory cell is higher than the selection read voltage, the k-th memory cell may be an off cell. In an example case in which the k-th memory cell is an off cell, a channel may be separated at the k-th memory cell. That is, a lower channel of the k-th memory cell may receive a ground voltage from the common source line CSL, and an upper channel of the k-th memory cell may have a negative channel voltage.

A channel voltage difference may occur between a lower channel and an upper channel with the k-th memory cell interposed the lower channel and the upper channel. Due to the channel voltage difference, hot carrier injection (HCl) may occur in an adjacent memory cells MCk+1 and/or MCk−1. For this reason, threshold voltages of memory cells connected to adjacent word lines WLk+1 and/or WLk−1 may be distorted. For example, the threshold voltages of memory cells in the erased state E0 may rise to enter the programmed state.

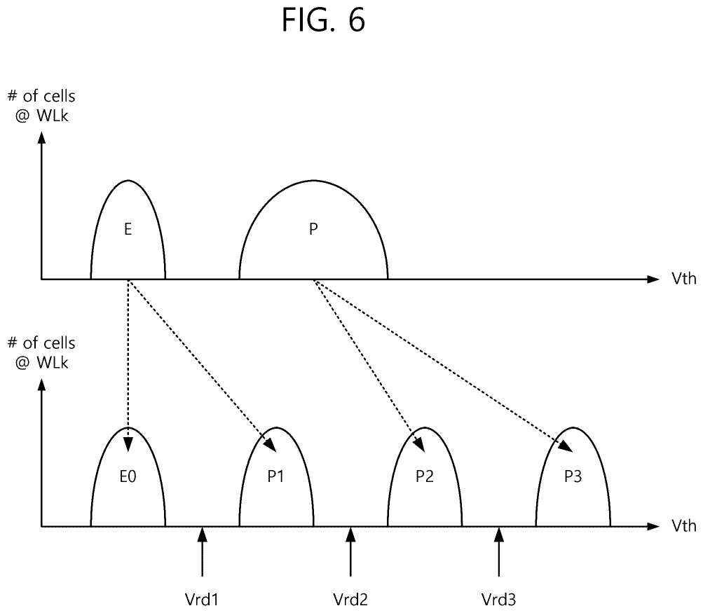

FIG. 6 is a diagram illustrating a method for reducing word line coupling of the memory device illustrated in FIG. 2. For example, FIG. 6 illustrates a program method for storing 2-bit data per cell and reducing word line coupling. In FIG. 6, the E state (e.g., erase state) and P state (e.g., program state) show threshold voltage distributions of memory cells after a lower page program procedure, and the states E0, P1, P2 and P3 show threshold voltage distributions of the memory cells after an upper page program procedure.

After the lower and upper pages are programmed, each of the memory cells may have one of four program states E0, P1, P2, and P3. For example, after the lower page is programmed, the memory cells belonging to the E state may be programmed to the E0 or P1 state, and the memory cells belonging to the P state may be programmed to the P2 or P3 state. The program states (E0, P1, P2, P3) may be determined using the read voltages (Vrd1, Vrd2, Vrd3).

In an example case in which M-bit data (M being an integer of 2 or more) are stored in each memory cell, threshold voltages of memory cells of a k-th word line may be shifted when an upper page is programmed at memory cells of an (k+1)-th word line. That is, threshold voltage distributions of the memory cells of the k-th word line may widen due to the word line coupling, compared to threshold voltage distributions before the upper page is programmed at the memory cells of the (k+1)-th word line. In other words, because not all the memory cells of the k-th word line but some of the memory cells of the k-th word line selectively suffer from (or experience) the word line coupling when the upper page is programmed at the memory cells of the (k+1)-th word line, a threshold voltage distribution widens.

A memory cell, which has a coupling influence on a memory cell of the k-th word line, from among the memory cells of the (k+1)-th word line is referred to as an “aggressor cell”. The (k+1)-th word line connected with the aggressor cell is referred to as an “aggressor word line”. Aggressor cells may constitute one or more aggressor cell groups depending on the degree (or magnitude) of coupling that memory cells of the k-th word line experience or depending on a way to program. Memory cells, which do not have a coupling influence on memory cells of the k-th word lines, from among the memory cells of the (k+1)-th word line may also constitute one group.

The remaining memory cells of the (k+1)-th word line other than the aggressor cells may be defined as “non-aggressor cells”. Each of the aggressor cells and the non-aggressor cells may have one of the program states described with reference to FIG. 6. According to the above definition, the memory cells of the k-th word line may be classified into memory cells experiencing the coupling and memory cells not experiencing the coupling. For this reason, a threshold voltage distribution may widen. A program operation for the (k+1)-th aggressor word line that provides the word line coupling to the memory cells of the k-th word line may be variably determined depending on an address scramble manner.

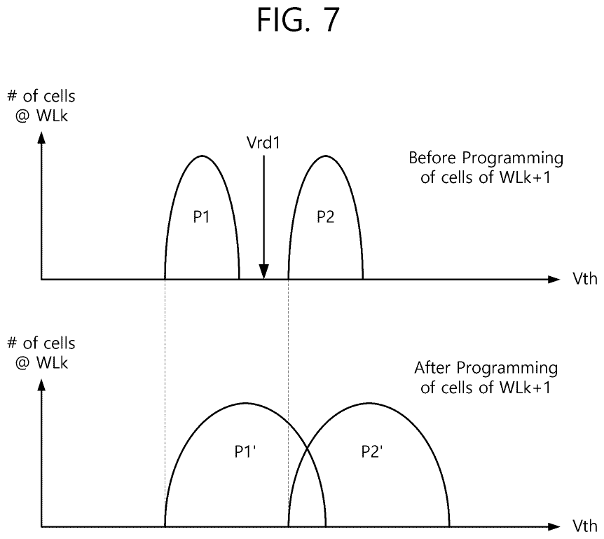

FIG. 7 is a diagram illustrating threshold voltage distributions associated with memory cells of an k-th word line before and after word line coupling caused when memory cells of an (k+1)-th word line are programmed. In an example illustrated in FIG. 7, there are two adjacent program states (e.g., P1 and P2) associated with the memory cells of the k-th word line before the memory cells of the (k+1)-th word line are programmed, that is, before the word line coupling.

The program states P1′ and P2′ illustrated in FIG. 7 show threshold voltage distributions associated with the memory cells of the k-th word line after the memory cells of the k-th word line experience the threshold voltage shift corresponding to the word line coupling caused when the memory cells of the (k+1)-th word line are programmed. The program states P1′ and P2′ show all threshold voltage distributions associated with memory cells that experience the word line coupling and the memory cells that do not experience the word line coupling, the word line coupling caused when the memory cells of the (k+1)-th word line are programmed.

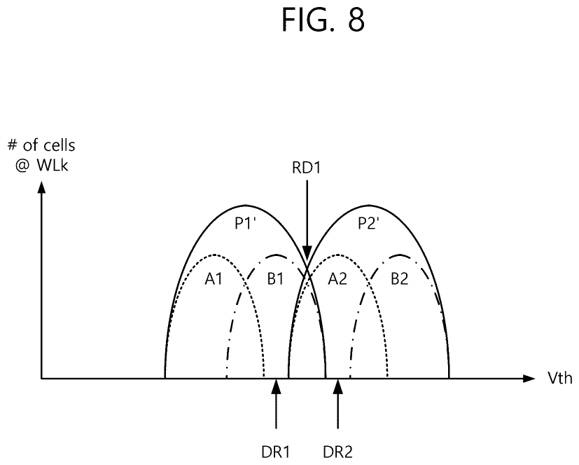

FIG. 8 is a diagram illustrating all threshold voltage distributions corresponding to memory cells experiencing the coupling and memory cells not experiencing the coupling. In an example of FIG. 8, threshold voltage distributions A1 and A2 show threshold voltage distributions of memory cells that do not experience the threshold voltage shift due to the word line coupling (or do not experience the word line coupling). Threshold voltage distributions B1 and B2 show threshold voltage distributions of memory cells that experience the threshold voltage shift due to the word line coupling (or experience the word line coupling). That is, the threshold voltage distributions B1 and B2 show the threshold voltage shift of memory cells that are previously programmed to have the program states A1 and A2.

Programmed memory cells of the k-th word line may belong to the threshold voltage distributions A1 and A2 of memory cells not experiencing the coupling influence or the threshold voltage distributions B1 and B2 of memory cells experiencing the coupling influence, depending on the threshold voltage shift caused by the programming of the memory cells of the (k+1)-th word line. A first read voltage DR1 may be used to read memory cells not experiencing the coupling influence, that is, to distinguish memory cells in the threshold voltage distributions A1 and A2. A second read voltage DR2 may be used to read memory cells experiencing the coupling influence, that is, to distinguish memory cells in the threshold voltage distributions B1 and B2.

To reduce a read error caused by the word line coupling, two read operations may be performed on one threshold voltage distribution or one program state (corresponding to a distribution not experiencing the coupling influence and a distribution experiencing the coupling influence) by using the first and second read voltages DR1 and DR2. The number of read operations that are performed on one program state may be determined depending on the number of groups including aggressor cells (or program states causing the coupling). For example, aggressor cells may constitute one group or may constitute two or more groups. In an example case in which aggressor cells constitute one group, two read operations may be performed. In an example case in which aggressor cells constitute two groups, three read operations may be performed.

Referring to FIG. 8, in the example case in which the read operation is performed when aggressor cells constitute one group, the read operation using the first read voltage DR1 may be performed to distinguish memory cells belonging to the distributions A1 and A2 not experiencing the coupling influence, and the read operation using the second read voltage DR2 may be performed to distinguish memory cells belonging to the distributions B1 and B2 experiencing the coupling influence.

The memory cells on which the read operation is performed by using the first read voltage DR1 and the memory cells on which the read operation is performed by using the second read voltage DR2 may be distinguished based on data read from memory cells of an upper word line. According to the above description, the read operation may be first performed on memory cells of an upper word line (or an adjacent word line) of a selection word line before the read operations associated with the memory cells of the selection word line. A set of read operations described above is referred to as a “data recover read operation”. The first and second read voltages DR1 and DR2 are respectively referred to as “first and second data recover read voltages”.

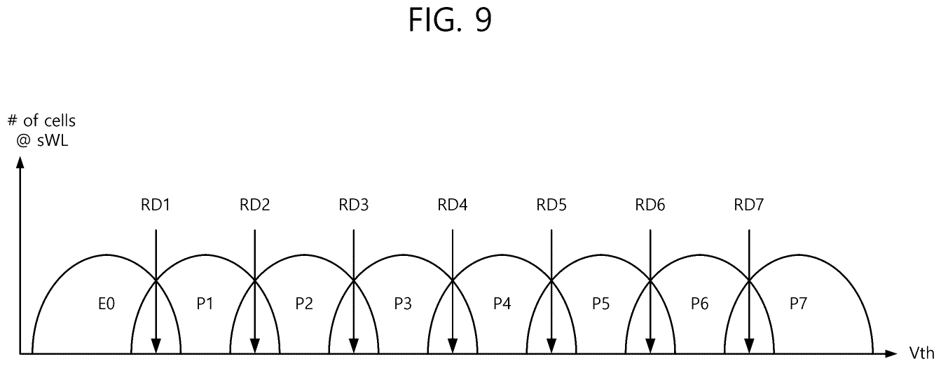

FIG. 9 is a graph illustrating states in which a plurality of memory cells are degraded, according to an embodiment. Referring to FIG. 9, threshold voltage distributions of the plurality of memory cells may be degraded due to various factors. The various factors may include, but not be limited to, charge leakage, read disturbance, program disturbance, coupling between adjacent memory cells, temperature change, voltage change, and the degradation of memory cells due to repeated program and erase operations.

That is, the threshold voltage distributions of the memory cells connected to the selection word line sWL may be distorted, widened, and shifted by the word line coupling of the adjacent memory cells. However, the disclosure is not limited thereto, and as such, according to another embodiment, during a retention period, a degree of charge loss of selection memory cells may vary due to the influence of states of adjacent memory cells, and thus, a degree to which a threshold voltage distribution of each of the selection memory cells widens may be further increased.

According to a degree of degradation of the threshold voltage distributions, a read operation performed by using related art read voltages (e.g., the first to seventh read voltages Vrd1 to Vrd7 shown in FIG. 5B) may cause a read fail. Accordingly, a read operation may be performed again by using first to seventh data recovery read voltages RD1 to RD7 as shown in FIG. 9.

However, in an example case in which the degree of degradation of the threshold voltage distributions is high (for example, higher than a threshold value), it may be difficult to determine states E0 and P1 to P7 of a triple level cell (TLC) even by using the first to seventh data recovery read voltages RD1 to RD7. Thus, patterns coupled to selection memory cells connected to a selection word line may be classified according to a state of adjacent memory cells connected to at least one adjacent word line that is physically adjacent to the selection word line. Accordingly, it may be necessary to obtain subdivided read voltages.

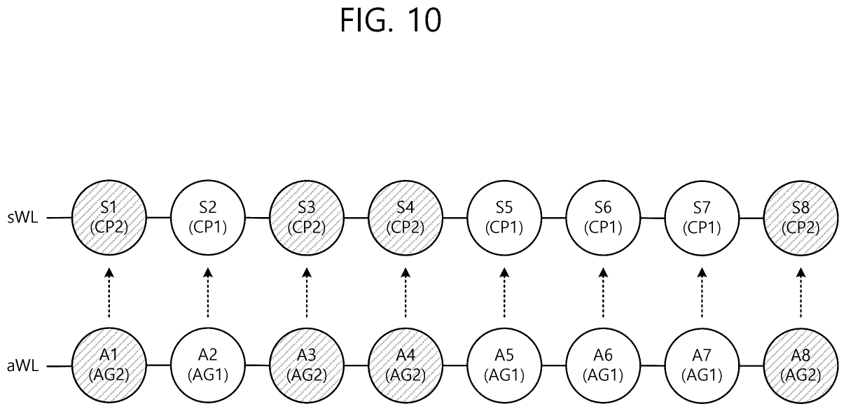

FIG. 10 is a diagram illustrating a coupling pattern and an aggressor cell group, according to an embodiment. Referring to FIG. 10, a selection word line sWL may include a plurality of selection memory cells S1 to S8. An adjacent word line aWL may include a plurality of adjacent memory cells A1 to A8. FIG. 10 illustrates an example in which the number of selection memory cells S1 to S8 is eight (8) and the number of adjacent memory cells A1 to A8 is eight (8). However, the present disclosure is not limited in this regard, and as such, according to another embodiment, the number of selection memory cells and the number of adjacent memory cells may be different than eight.

In some embodiments, the adjacent word line aWL may be a single word line. In an example case in which the selection word line sWL is an uppermost word line, such as an m-th word line WLm, the adjacent word line aWL may be an (m−1)-th word line WLm−1. In another example case in which the selection word line sWL is a lowermost word line, such as a first word line WL1, the adjacent word line aWL may be a second word line WL2. Since data is not stored in the dummy memory cells connected to the dummy word line, the dummy memory cells may not have a coupling effect on the memory cells adjacent to the dummy memory cells. Therefore, the dummy word line may not be included in the adjacent word line aWL.

The plurality of selection memory cells S1 to S8 may be respectively adjacent to the plurality of adjacent memory cells A1 to A8. For example, a first selection memory cell S1 may be adjacent to a first adjacent memory cell A1, and a second selection memory cell S2 may be adjacent to a second adjacent memory cell A2. Similarly, an eighth selection memory cell S8 may be adjacent to an eighth adjacent memory cell A8. Because each selection memory cell may be coupled with an adjacent memory cell adjacent thereto, degradation may occur in each selection memory cell.

In some embodiments, each of the selection memory cells A1 to A8 may have a coupling pattern according to an aggressor cell group of each of the plurality of adjacent memory cells A1 to A8. For example, the aggressor cell group may include a first aggressor cell group AG1 and a second aggressor cell group AG2. The selection memory cells S2, S5, S6, and S7, which are adjacent to the adjacent memory cells A2, A5, A6, and A7 included in the first aggressor cell group AG1, may have a first coupling pattern CP1. The selection memory cells S1, S3, S4, and S8, which are adjacent to the adjacent memory cells A1, A3, A4, and A8 included in the second aggressor cell group AG2, may have a second coupling pattern CP2. However, the present disclosure is not limited in this regard. According to another embodiment, a number of aggressor cell groups and/or a number of coupling patterns may be different than two. Hereinafter, a method of grouping a plurality of aggressor cell groups for the plurality of adjacent memory cells A1 to A8 will be described.

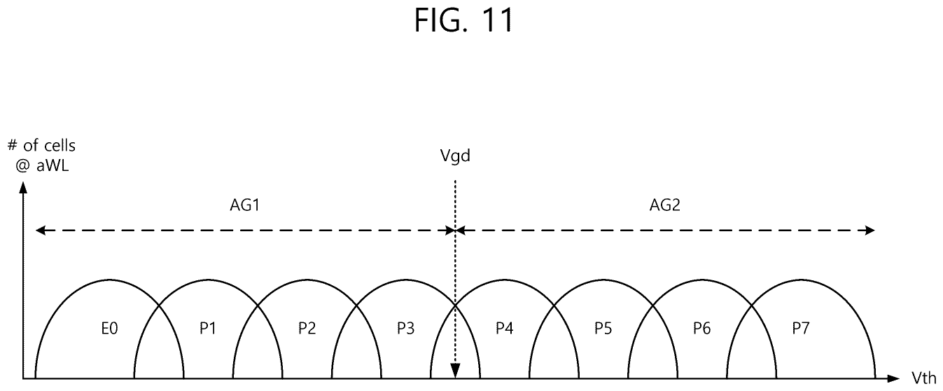

FIG. 11 is a graph illustrating a method of grouping a plurality of aggressor cell groups, according to an embodiment. In FIG. 11, an abscissa (x-coordinate) denotes a threshold voltage Vth of a memory cell, and an ordinate (y-coordinate) denotes the number of adjacent memory cells (e.g., # of cells @ aWL) connected to an adjacent word line aWL and/or a memory cell count value.

By one group determination read voltage Vgd, each of adjacent memory cells connected to the adjacent word line aWL may be grouped into two (2) aggressor cell groups, for example, a first aggressor cell group AG1 and a second aggressor cell group AG2. In an embodiment, the first aggressor cell group AG1 and the second aggressor cell group AG2, which are distinguished from each other by one group determination read voltage Vgd, may be referred as a non-aggressor cell group and an aggressor cell group, respectively.

The first aggressor cell group AG1 may include a memory cell having a threshold voltage lower than one group determination read voltage Vgd. The second aggressor cell group AG2 may include a memory cell having a threshold voltage higher than one group determination read voltage Vgd. In an example, when adjacent memory cells A2, A5, A6, and A7 have a threshold voltage lower than one group determination read voltage Vgd, the adjacent memory cells A2, A5, A6, and A7 may belong to the first aggressor cell group AG1. In another example, when adjacent memory cells A1, A3, A4, and A8 have a threshold voltage higher than one group determination read voltage Vgd, the adjacent memory cells A2, A5, A6, and A7 may belong to the second aggressor cell group AG2.

A coupling pattern of each of the selection memory cells S1 to S8 may be determined according to an aggressor cell group to which an adjacent memory cell corresponding to the coupling pattern belongs.

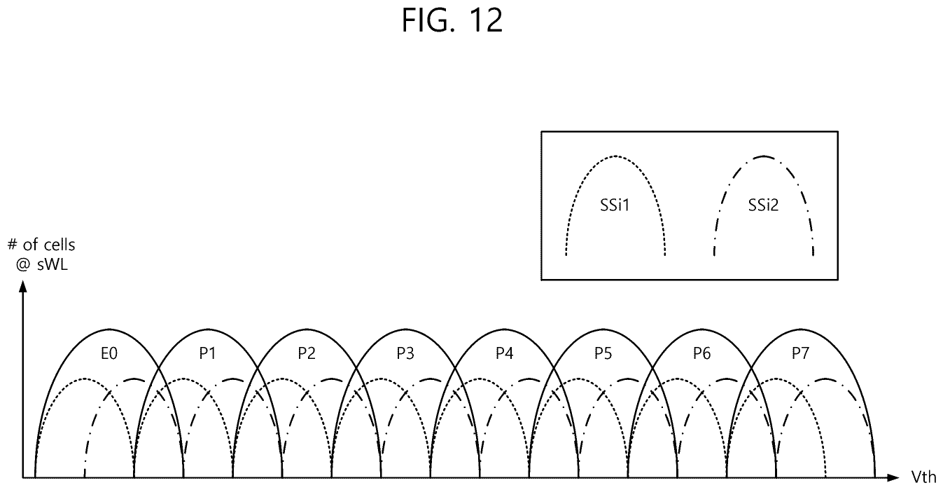

FIG. 12 is a graph illustrating sub-threshold voltage distributions based on the plurality of aggressor cell groups, according to an embodiment. In FIG. 12, an abscissa denotes a threshold voltage Vth of a memory cell, and an ordinate denotes the number of selection memory cells (e.g., # of cells @ sWL) connected to a selection word line sWL and/or a memory cell count value.

The threshold voltage distributions of the selection memory cells may be divided into sub-threshold voltage distributions according to a coupling pattern of each selection memory cell. For example, each of states E0 and P1 to P7 of the selection memory cells may be subdivided into a first sub-state SSi1 corresponding to a first coupling pattern CP1 and a second sub-state SSi2 corresponding to a second coupling pattern CP2.

The sum of areas of the first and second sub-states SSi1 and SSi2 corresponding to each state may be equal to an area of each state. For example, the sum of areas of the first and second sub-states SSi1 and SSi2 corresponding to an erase state E may be equal to an area of the erase state E0. The area of the first sub-state SSi1 (or the area of the second sub-state SSi2) corresponding to the erase state E0 may correspond to half the area of the erase state E0.

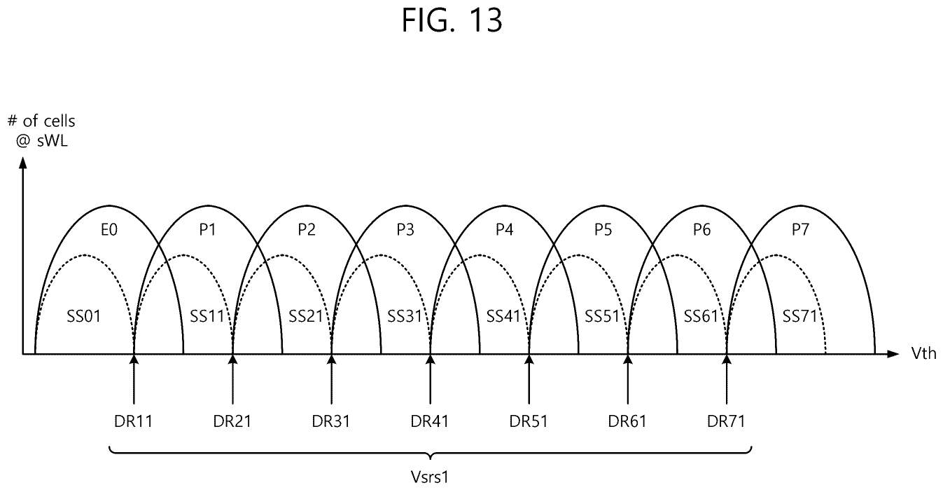

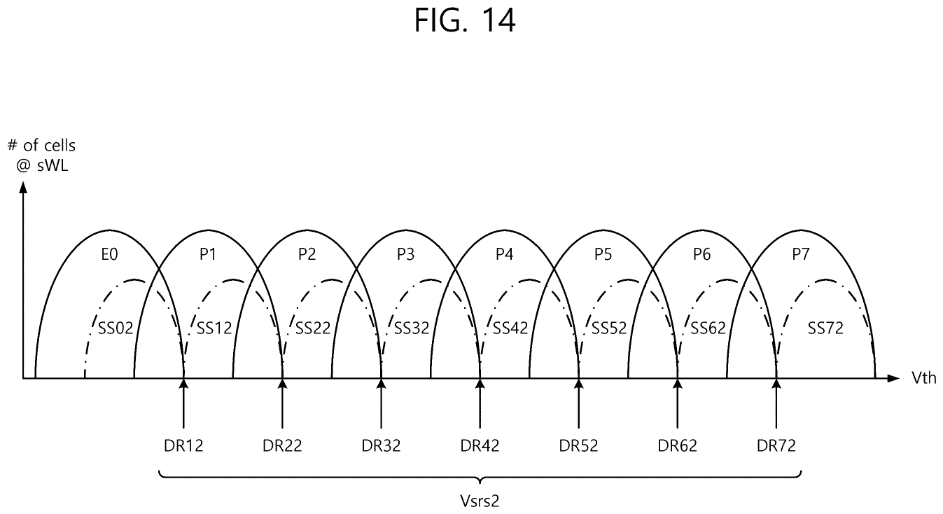

FIGS. 13 and 14 are graphs illustrating sub-read voltage sets for the sub-threshold voltage distributions of FIG. 12, according to an embodiment. For example, FIG. 13 illustrates first sub-states SS01 to SS71 of selection memory cells having a first coupling pattern CP1, and FIG. 14 illustrates second sub-states SS02 to SS72 of selection memory cells having a second coupling pattern CP2. In FIGS. 13 and 14, an abscissa denotes a threshold voltage Vth of a memory cell, and an ordinate denotes the number of selection memory cells (e.g., # of cells @ sWL) connected to a selection word line sWL and/or a memory cell count value.

Referring to FIG. 13, in an example case in which the data recovery read voltages DR11 to DR71 (e.g., a first sub-read voltage set Vsrs1) for determining the first sub-states SS01 to SS71 are obtained, data stored in the selection memory cells having the first coupling pattern CP1 may be obtained by performing a read operation by using the first sub-read voltage set Vsrs1.

Referring to FIG. 14, in an example case in which the data recovery read voltages DR12 to DR72 (e.g., a second sub-read voltage set Vsrs2) for determining the second sub-states SS02 to SS72 are obtained, data stored in the selection memory cells having the second coupling pattern CP2 may be obtained by performing a read operation by using the second sub-read voltage set Vsrs2. A method of calculating the first sub-read voltage set Vsrs1 and the second sub-read voltage set Vsrs2 is described below.

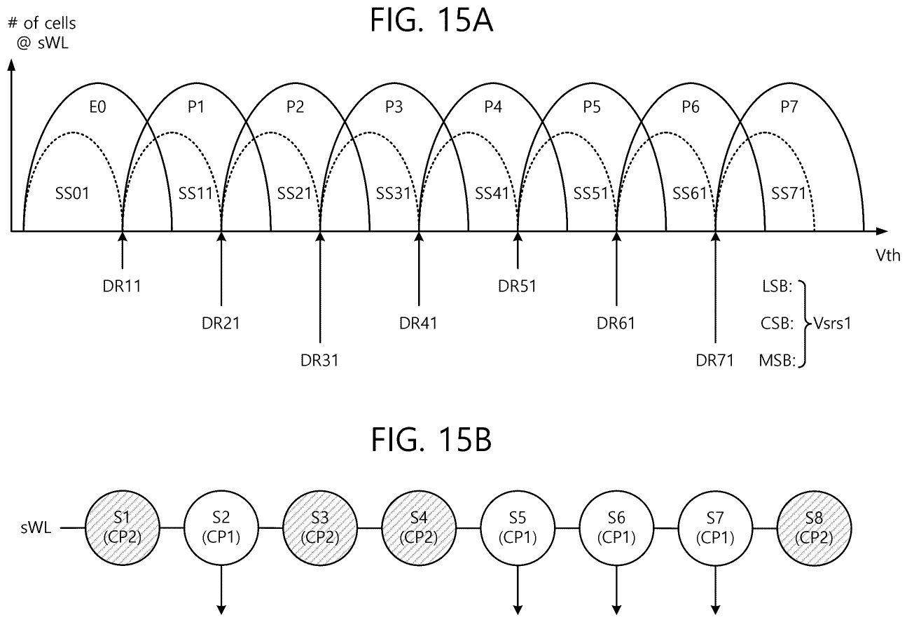

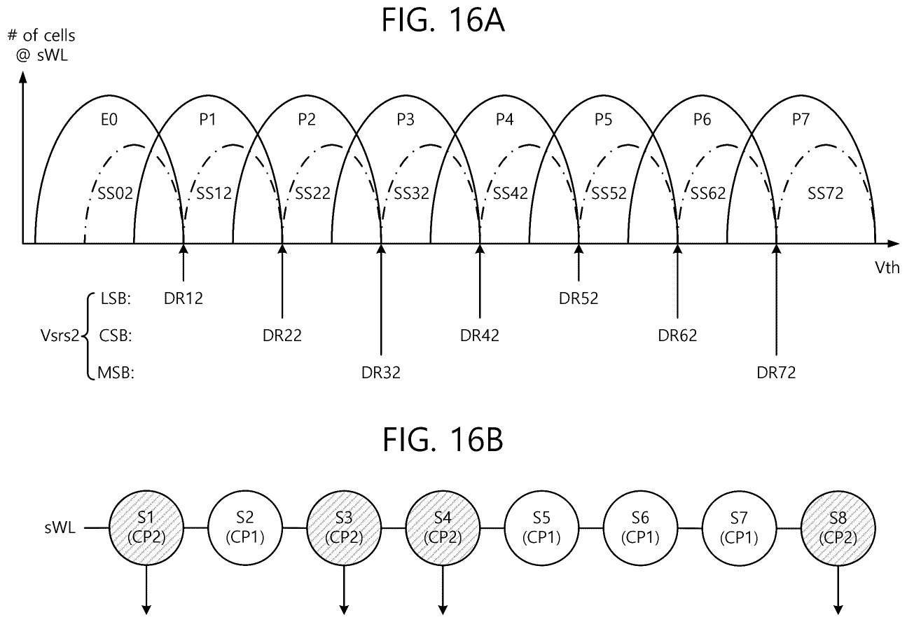

FIGS. 15A and 15B are diagrams illustrating a read operation using the sub-read voltage set shown in FIG. 13 and FIGS. 16A and 16B are diagrams illustrating a read operation using the sub-read voltage set shown in FIG. 14.

Referring to FIGS. 15A and 15B, by applying a first sub-read voltages DR11 to DR71 corresponding to the first coupling pattern CP1 to the selection word line sWL, a first data recovery read operation of reading data from selection memory cells S2, S5, S6, and S7 having the first coupling pattern CP1 may be performed. The first sub-read voltages DR11 to DR71 may be a first sub-read voltage set Vsrs1. Data read from the selection memory cells S1, S3, S4, and S8 that does not have the first coupling pattern CP1 (e.g., that has the second coupling pattern CP2) may be ignored.

The first sub-read voltage set Vsrs1 may be applied from the first sub-read voltage DR11 having the lowest voltage level to the seventh sub-read voltage DR71 having the highest voltage level. According to an embodiment, the sub-read voltages DR11 to DR71 may be applied in different stages. For example, in the least significant bit (LSB) stage, the first and fifth sub-read voltages DR11 and DR51 may be applied, in the central significant bit (CSB) stage, the second, fourth and sixth sub-read voltages DR21, DR41, and DR61 may be applied, and in the most significant bit (MSB) stage, the third and seventh sub-read voltages DR31 and DR71 may be applied. The order in which the sub-read voltages DR11 to DR71 are applied to the selection word line sWL may be determined in various ways. For example, the order of the stages may be the LSB stage, the CSB stage, and the MSB stage.

Referring to FIGS. 16A and 16B, by applying a second sub-read voltages DR11 to DR71 corresponding to the second coupling pattern CP2 to the selection word line sWL, a second data recovery read operation of reading data from selection memory cells S1, S3, S4, and S8 having the second coupling pattern CP2 may be performed. The second sub-read voltages DR12 to DR72 may be a second sub-read voltage set Vsrs2. Data read from the selection memory cells S2, S5, S6, and S7 that does not have the second coupling pattern CP2 (e.g., that has the first coupling pattern CP1) may be ignored.

According to an embodiment, the sub-read voltages DR12 to DR72 may be applied in different stages. For example, in the LSB stage, the first and fifth sub-read voltages DR12 and DR52 may be applied, in the CSB stage, the second, fourth and sixth sub-read voltages DR22, DR42, and DR62 may be applied, and finally in the MSB stage, the third and seventh sub-read voltages DR32 and DR72 may be applied. The order in which the sub-read voltages DR12 to DR72 are applied to the selection word line sWL may be determined in various ways. For example, the order of the stages may be the LSB stage, the CSB stage, and the MSB stage.

A read operation may be performed on the plurality of selection memory cells S1 to S8 having a plurality of coupling patterns (e.g., CP1, CP2), based on a plurality of sub-read voltage sets (e.g., Vsrs1 and Vsrs2). The read operation performed by using the sub-read voltage sets may be referred to as a data recovery read operation. Hereinafter, a method of calculating the plurality of sub-read voltage sets Vsrs1 and Vsrs2 is described below.

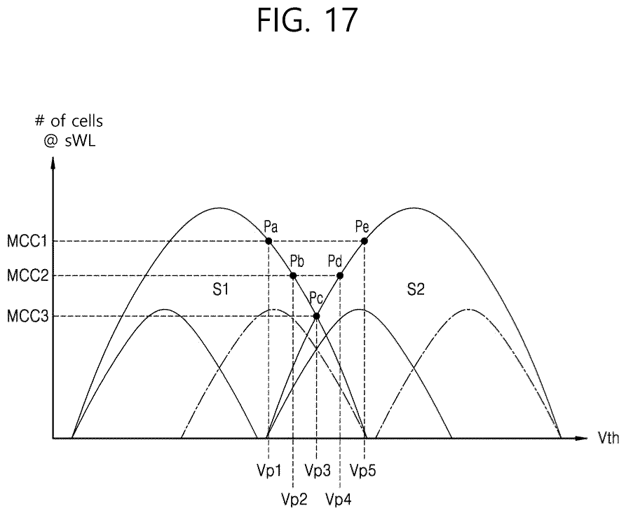

FIG. 17 is a graph illustrating a valley search operation and a method of obtaining a plurality of points, according to an embodiment. In FIG. 17, an abscissa denotes a threshold voltage Vth of a memory cell, and an ordinate denotes the number of a selection memory cell (e.g., # of cells @ sWL) connected to a selection word line sWL and/or a memory cell count value.

A first state S1 and a second state S2 may correspond to two (2) adjacent states of states (e.g., states E0, P1 to P7 of a TLC) of selection memory cells. For example, the first state S1 may be an erase state E0, and the second state S2 may be a first program state P1. In another example, the first state S1 may be a sixth program state P6, and the second state S2 may be a seventh program state P7. However, the present disclosure is not limited in this regard.

A memory controller (e.g., a memory controller 1200 in FIG. 1) may control a memory device (e.g., a memory device 1100 in FIG. 1) to perform a valley search operation. The valley search operation may refer to an operation of searching for a valley between threshold voltage distributions of the selection memory cells connected to the selection word line sWL, from among a plurality of word lines. The valley search operation may be an operation of searching for a valley formed at a point (e.g., Pc) where a threshold voltage distribution of the first state S1 intersects with a threshold voltage distribution of the second state S2.

In an embodiment, the memory device 1100 may perform the valley search operation. For example, the memory device 1100 may apply a plurality of read voltages for searching for the valley to the selection word line sWL, obtain memory cell count values indicating the numbers of OFF cells, and search, as a valley, a point including a smallest memory cell count value and a read voltage corresponding to the smallest memory cell count value (e.g., Pc).

In some embodiments, during the valley search operation, the memory device 1100 may perform a read operation five (5) times, for example. Accordingly, the memory controller 1200 may obtain five (5) points (e.g., first to fifth points Pa, Pb, Pc, Pd, and Pe). For example, first to fifth read voltages Vp1 to Vp5 may be sequentially applied to the selection word line sWL. In this case, voltage level intervals between the first to fifth read voltages Vp1 to Vp5 may be equal.

For example, a voltage level interval between a k-th read voltage and a (k+1)-th read voltage may be constant (e.g., k may be an integer in the range of one (1) to four (4)). By sequentially applying the first to fifth read voltages Vp1 to Vp5 to the selection word line sWL, a memory cell count value may be obtained that indicates the number of memory cells (e.g., OFF cells) having a threshold voltage higher than each read voltage.

In an embodiment, each point points (e.g., first to fifth points Pa, Pb, Pc, Pd, and Pe) may be a two-dimensional (2D) coordinate including a read voltage level and the memory cell count value. For example, when the voltage level intervals between the first to fifth read voltages Vp1 to Vp5 are equal to each other and an area of the first state S1 is equal to an area of the second state S2, a memory cell count value of each of the first point Pa and the fifth point Pe may be substantially equal to a first memory cell count value MMC1, and a memory cell count value of each of the second point Pb and the fourth point Pd may be substantially equal to a second memory cell count value MMC2.

The first point Pa may include a level of the first read voltage Vp1 and the first memory cell count value MMC1, the second point Pb may include a level of the second read voltage Vp2 and the second memory cell count value MMC2, the third point Pc may include a level of the third read voltage Vp3 and a third memory cell count value MMC3, the fourth point Pd may include a level of the fourth read voltage Vp4 and a fourth memory cell count value (e.g., the second memory cell count value MMC2), and the fifth point Pe may include a level of the fifth read voltage Vp5 and a fifth memory cell count value (e.g., the first memory cell count value MMC1). From among the first to fifth points Pa, Pb, Pc, Pd, and Pe, the third point Pc corresponding to the smallest memory cell count value may correspond to the valley, and a point corresponding to the valley may be referred to as a valley point.

In an embodiment, the first to fifth read voltages Vp1 to Vp5 for obtaining the first to fifth points Pa, Pb, Pc, Pd, and Pe may be applied to the selection word line sWL in ascending powers (e.g., voltage levels). For example, a read operation using the first read voltage Vp1 may be performed first, subsequent read operations may be performed in increasing order of voltage levels (e.g., Vp2, Vp3, and Vp4), and a read operation using the fifth read voltage Vp5 may be performed last.

However, the disclosure is not limited thereto, and as such, according to another embodiment, the first to fifth read voltages Vp1 to Vp5 for obtaining the first to fifth points Pa, Pb, Pc, Pd, and Pe may be applied to the selection word line sWL in descending powers (e.g., voltage levels). For example, a read operation using the fifth read voltage Vp5 may be performed first, subsequent read operations may be performed in increasing order of voltage levels (e.g., Vp3, Vp3, and Vp2), and a read operation using the first read voltage Vp1 may be performed last.

According to another embodiment, during the valley search operation, the memory device 1100 may obtain the first to fifth points Pa, Pb, Pc, Pd, and Pe by performing five (5) read operations starting from a preset read voltage. For example, the five (5) read operations may be performed in a preset order. Valley search operations may be performed on the states E0 and P1 to P7 of the selection memory cells, and the first to fifth points Pa, Pb, Pc, Pd, and Pe may be obtained for every two (2) states. The memory device 1100 may provide data indicating the first to fifth points Pa, Pb, Pc, Pd, and Pe to the memory controller 1200.

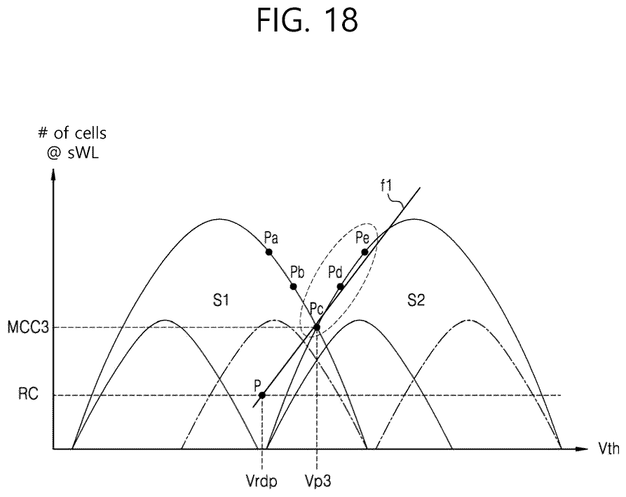

FIG. 18 is a graph illustrating a method of obtaining a first voltage level in a first function, according to an embodiment. The memory controller 1200 may set a first function f1, based on a valley point and at least two (2) points having a higher level than a read voltage included in the valley point, from among a plurality of points.

For example, the valley point may be a third point Pc from among five (5) points (e.g., first to fifth points Pa, Pb, Pc, Pd, and Pe). Thus, points having levels higher than a level of a threshold read voltage Vp3 of the third point Pc may be the fourth point Pd and the fifth point Pe. By using a linear regression model, the memory controller 1200 may set a first linear function, which may be closest to the third to fifth points Pc, Pd, and Pe, as the first function f1. For example, the first linear function may approximate a line that crosses, within a threshold value, the third to fifth points Pc, Pd, and Pe. The threshold value may be predetermined value. That is, the first linear function may minimize distances between the line and the third to fifth points Pc, Pd, and Pe.

The first function f1 may be expressed using the following equation:

$$log y = \hat{a} \times x \times \hat{b} \qquad [ Equation 11 ]$$

In Equation 1, y represents a memory cell count value, â represents a predicted value of a slope of the first linear function (e.g., the first function f1), and \hat{b} denotes a predicted value of an intercept of an abscissa (e.g., x-axis).

The first function f1 may correspond to points (e.g., the third to fifth points Pc, Pd, and Pe) having read voltage levels higher than or equal to a valley read voltage level (e.g., a level of the third read voltage Vp3 of the third point Pc) of the valley point, from among the plurality of points (e.g., five (5) points Pa, Pb, Pc, Pd, and Pe). Although the first function f1 may be a linear function in the embodiment shown in FIG. 18, the present disclosure is not limited in this regard. For example, the first function f1 may be a nonlinear function.

The memory controller 1200 may obtain a point P corresponding to a reference count value RC in the first function f1 and obtain a first voltage level Vrdp corresponding to an abscissa coordinate (e.g., x coordinate) included in the point P. In a specific example, Equation 1 may be rewritten using the following equation:

$$Vrdp = ( log ( RC ) - \hat{b} ) / \hat{a} \qquad [ Equation 2 ]$$

In some embodiments, the reference count value RC may be smaller than a memory cell count value of the valley point. For example, when the valley point is the third point Pc, the reference count value RC may be smaller than a third memory cell count value MCC3.

In an embodiment, when the area of the first state S1 is equal to the area of the second state S2, an area of each sub-state (e.g., a first sub-state SSi1) corresponding to each state (e.g., the first state S1) may be half of the area of each state. Because a height ratio is geometrically equal to a ratio of a square root of an area, a memory cell count value corresponding to a height of the first sub-state SSi1 (and/or a second sub-state SSi2) may be 1/√2 times a height of each state (e.g., the first state S1). Accordingly, the reference count value RC may be 1/√2 times of the memory cell count value of the valley point.

For example, the reference count value RC may be 1/\sqrt{2} times the third memory cell count value MMC3. As the number of types of coupling patterns increases, a ratio of an area of one sub-state to an area of each state may be gradually reduced, and a memory cell count corresponding to a height of one sub-state may also be reduced in inverse proportion to a square root of the number of types of coupling patterns. Accordingly, the reference count value RC may be inversely proportional to the square root of the number of types of coupling patterns.

In another embodiment, when the area of the first state S1 is different from the area of the second state S2, an area of sub-states corresponding to the first state S1 may be different from an area of sub-states corresponding to the second state S2. In this case, the reference count value RC may be smaller than or equal to the square root of the number of types of coupling patterns.

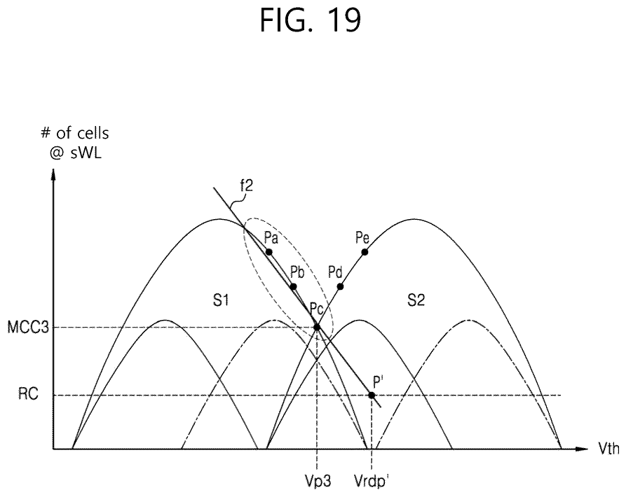

FIG. 19 is a graph illustrating a method of obtaining a second voltage level in a second function, according to an embodiment. The memory controller 1200 may set a second function f2, based on a valley point and at least two (2) points having a lower level than a read voltage included in the valley point, from among a plurality of points.

For example, when the valley point is the third point Pc, points having levels lower than a level of a third read voltage Vp3 of the third point Pc may be the first point Pa and the second point Pb. By using a linear regression model, the memory controller 1200 may set a second linear function, which may be closest to the first to third points Pa, Pb, and Pc, as the second function f2.

For example, the second linear function may approximate a line that crosses, within a predetermined threshold, the first to third points Pa, Pb, and Pc. That is, the first linear function may minimize distances between the line and the first to third points Pa, Pb, and Pc. The second function f2 may be expressed using the following equation:

$$log y = \hat{c} \times x + \hat{d} \} \qquad [ Equation 3 ]$$

In Equation 3, y represents a memory cell count value, ĉ represents a predicted value of a slope of the second linear function, and \hat{d} represents a predicted value of an intercept of an abscissa (e.g., x-axis).

The second function f2 may correspond to points (e.g., the first to third points Pa, Pb, and Pc) having read voltage levels equal to or smaller than a valley read voltage level (e.g., the level of the third read voltage Vp3 of the third point Pc) of the valley point, from among the plurality of points (e.g., the first to fifth points Pa, Pb, Pc, Pd, and Pe). In some embodiments, the second function f2 may be a nonlinear function.

The memory controller 1200 may obtain a point P′ corresponding to a reference count value RC in the second function f2, and obtain a second voltage level Vrdp′ corresponding to an abscissa coordinate (e.g., x coordinate) included in the point P′. In a specific example, Equation 3 may be rewritten based on x using the following equation:

$${Vrdp}^{′} = ( log ( RC ) - \hat{d} ) / \hat{c} \qquad [ Equation 4 ]$$

In some embodiments, the reference count value RC may be smaller than a memory cell count value of the valley point.

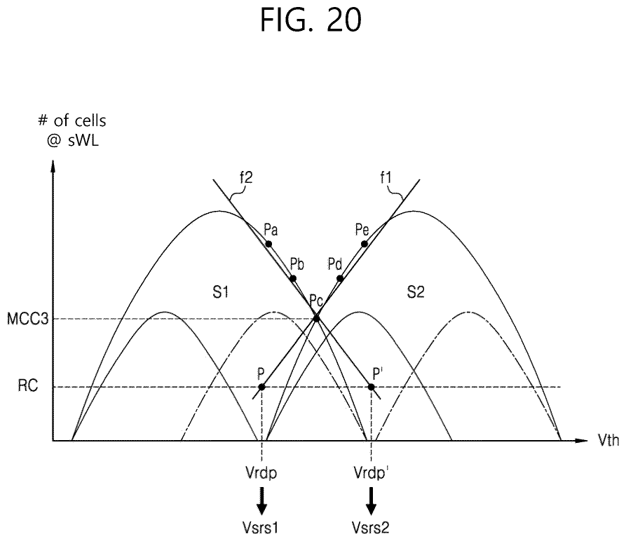

FIG. 20 is a graph illustrating a method of obtaining sub-read voltage sets, according to an embodiment. The memory controller 1200 may obtain sub-read voltage sets, based on a plurality of coupling patterns, a first voltage level Vrdp, and a second voltage level Vrdp′.

For example, the plurality of coupling patterns may include a first coupling pattern CP1 and a second coupling pattern CP2. Thus, a sub-read voltage having the first voltage level Vrdp may be included in a first sub-read voltage set Vsrs1 corresponding to the first coupling pattern CP1, and a sub-read voltage having the second voltage level Vrdp′ may be included in a second sub-read voltage set Vsrs2 corresponding to the second coupling pattern CP2.

According to the above-described method of calculating the first voltage level Vrdp and the second voltage level Vrdp′, the sub-read voltages DR11 to DR71 shown in FIG. 13 and the sub-read voltages DR12 to DR72 shown in FIG. 14 may be obtained. An optimum read voltage may be obtained according to an aggressor cell group of an adjacent memory cell, and thus, the performance of a read operation may be improved.

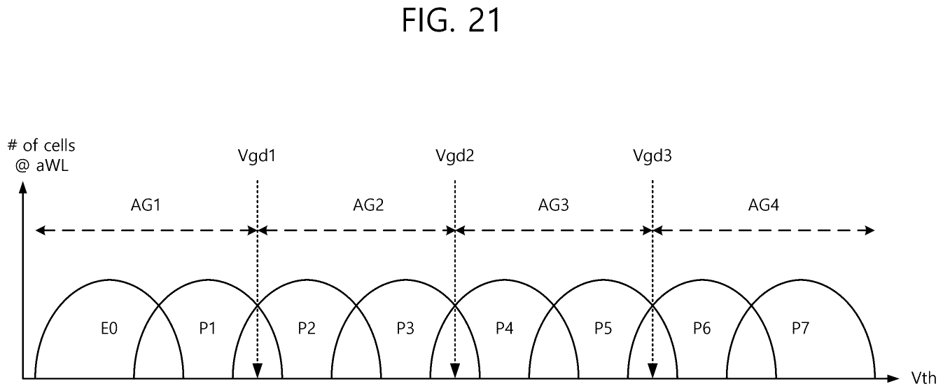

FIG. 21 is a graph illustrating a method of grouping a plurality of aggressor cell groups, according to an embodiment. In FIG. 21, an abscissa denotes a threshold voltage Vth of a memory cell, and an ordinate denotes the number of adjacent memory cells (e.g., # of cells @ aWL) connected to an adjacent word line aWL and/or a memory cell count value.

Referring to FIG. 21, by three group determination read voltages Vgd1, Vgd2, and Vgd3, each of adjacent memory cells connected to the adjacent word line aWL may be grouped into four (4) aggressor cell groups, for example, a first aggressor cell group AG1, a second aggressor cell group AG2, a third aggressor cell group AG3, and a fourth aggressor cell group AG4. In an embodiment, the first aggressor cell group AG1 may be referred as a non-aggressor cell group.

The first aggressor cell group AG1 may include a memory cell having a threshold voltage lower than one group determination read voltage Vgd1. The second aggressor cell group AG2 may include a memory cell having a threshold voltage higher than one group determination read voltage Vgd1 and lower than the second group determination read voltage Vgd2. The third aggressor cell group AG3 may include a memory cell having a threshold voltage higher than the second group determination read voltage Vgd2 and lower than the third group determination read voltage Vgd3. The fourth aggressor cell group AG4 may include a memory cell having a threshold voltage higher than the third group determination read voltage Vgd3.

Three group determination read voltages Vgd1, Vgd2, and Vgd3 may be set so that the number of states belonging to each aggressor cell group is the same. However, the present disclosure is not limited in this regard. Three group determination read voltages Vgd1, Vgd2, and Vgd3 may be set so that the number of states belonging to each aggressor cell group is not the same. However, the disclosure is not limited thereto, and as such, the number of types of aggressor cell groups may be different than four and the group determination read voltages may be different than three.

In an example case in which the number of types of aggressor cell groups is four, the number of types of coupling patterns may also be four. For example, the plurality of coupling patterns may include first to fourth coupling patterns corresponding to the first to fourth aggressor cell groups AG1 to AG4, respectively. In FIG. 21, three group determination read voltages Vgd1, Vgd2, and Vgd3 are illustrated, however, the present disclosure is not limited in this regard. The memory controller 1200 may generate control signals to provide four or more group determination read voltages.

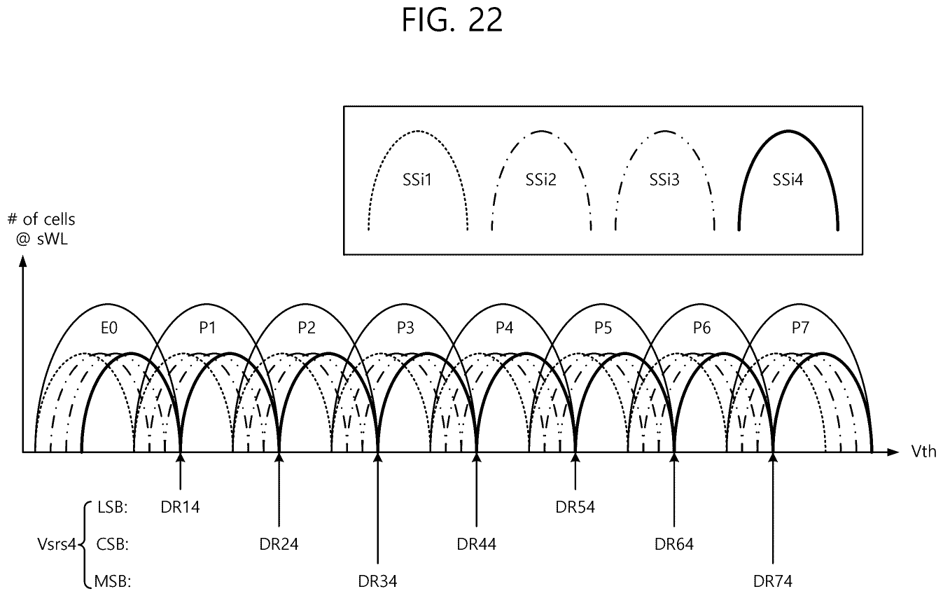

FIG. 22 is a graph illustrating sub-threshold voltage distributions, according to the plurality of aggressor cell groups, according to an embodiment. In FIG. 22, an abscissa denotes a threshold voltage Vth of a memory cell, and an ordinate denotes the number of selection memory cells (e.g., # of cells @ sWL) connected to a selection word line sWL and/or a memory cell count value.

In an example case in which the number of types of aggressor cell groups is four (4), each of the states E0, P1 to P7 of the selection memory cells may be subdivided into first to fourth sub-states SSi1 to SSi4 corresponding to each of the first to fourth coupling patterns. The first sub-state SSi1 may correspond to the first coupling pattern, the second sub-state SSi2 may correspond to the second coupling pattern, the third sub-state SSi3 may correspond to the third coupling pattern, and the fourth sub-state SSi4 may correspond to the fourth coupling pattern.

A data recovery read operation for reading data from selection memory cells having the fourth coupling pattern may be performed by applying sub-read voltages DR14 to DR74 corresponding to the fourth coupling pattern to the selection word line sWL. In this case, data read from selection memory cells not having the fourth coupling pattern may be ignored. The voltage applied to the selection word line sWL may be the fourth sub-read voltage set Vsrs4.

For example, the first and fifth sub-read voltages DR14 and DR54 may be applied in the LSB stage, the second, fourth and sixth sub-read voltages DR24, DR44, and DR64 may be applied in the CSB stage, and the third and seventh sub-read voltages DR34 and DR74 may be applied in the MSB stage. The order in which the fourth sub-read voltage set Vsrs4 is applied to the selection word line sWL may be determined in various ways.

The sub-read voltages corresponding to the first to third coupling patterns may also be applied to the selection word line sWL, similarly to the sub-read voltages corresponding to the fourth coupling pattern. Data recovery read operations for reading data from selection memory cells having the first to third coupling patterns may be performed.

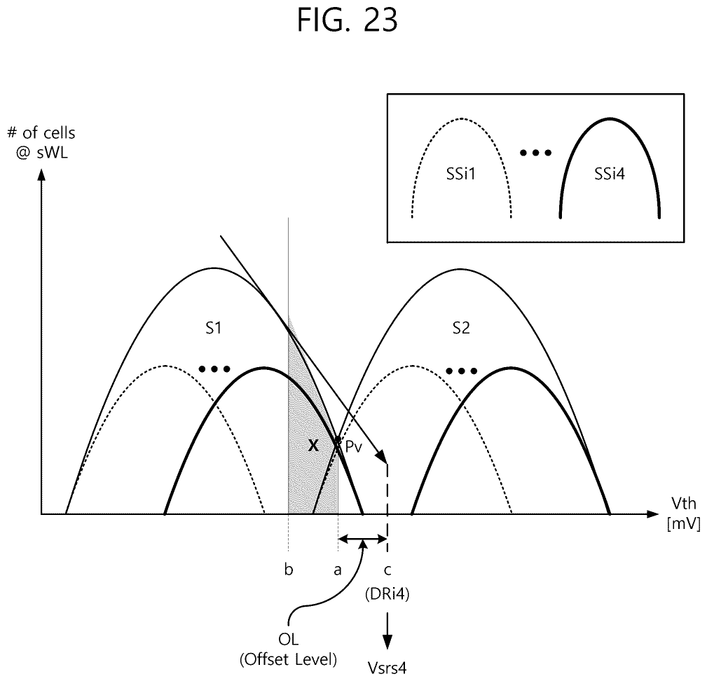

FIG. 23 are a graph illustrating sub-read voltage sets for the sub-threshold voltage distributions of FIG. 22, according to an embodiment. In FIG. 23, an abscissa denotes a threshold voltage Vth of a memory cell, and an ordinate denotes the number of selection memory cells (e.g., # of cells @ sWL) connected to a selection word line sWL and/or a memory cell count value.

The memory device 1100 may perform a valley search operation. The memory controller 1200 may obtain the valley point Pv. The memory controller 1200 may calculate the cell count value of a specific area (e.g., X) of the distribution once and then use this value to find the offset level OL for the data recovery read operation for each coupling pattern. Since the memory device 1100 may find the offset level with a single read operation, it may reduce the deterioration due to the read disturbance that may occur when performing multiple read operations and improve the operation speed.

The cell count value of a specific area (e.g., X area) of the distribution may be the number of cells between “a” and “b”. The cell count value of the X area may be calculated by finding a number of off cells (or on cells) in “a” and a number of off cells “b”, and using a difference between the number of off cells (or on cells) calculated in “a” and the number of off cells calculated in “b”. According to an embodiment, “a” may be a first voltage level corresponding to a valley point Pv and “b” may be a second voltage level for calculating the cell count value. For example, the first voltage level may be 0 mV and the second voltage level may be −100 mV. The memory device 1100 may provide the cell count value to the memory controller 1200.

Referring to FIGS. 1 and 23, the memory controller 1200 may calculate the offset level OL using the cell count value. The memory controller 1200 may calculate the offset level OL using table data in the read level set table 1230. However, the disclosure is not limited thereto, and as such, according to another embodiment, the offset value OL may be obtained in another manner. For example, the memory controller 1200 may calculate the offset level OL using a mathematical formula or a mathematical algorithm. The memory controller 1200 may find “c” using table data or a mathematical formula, etc. Here, the offset level OL may be a voltage level difference between “a” and “c”.

The memory device 1100 may apply three group determination read voltages Vgd1, Vgd2, and Vgd3 to the adjacent word line aWL under the control of the memory controller 1200. The memory controller 1200 may group the adjacent memory cells connected to the adjacent word line aWL into the first to fourth aggressor cell groups AG1 to AG4. And the memory controller 1200 may divide the coupling pattern of each of the selection memory cells into the first to fourth coupling patterns.

The memory controller 1200 may calculate the offset level OL of the adjacent states S1 and S2 of one coupling pattern (e.g., the fourth coupling pattern). The memory controller 1200 may calculate a sub-read voltage (e.g., DRi4) for an optimal data recovery read operation using the offset level OL. For example, the sub-read voltage DRi4 may be included in the fourth sub-read voltage set Vsrs4 corresponding to the fourth coupling pattern.

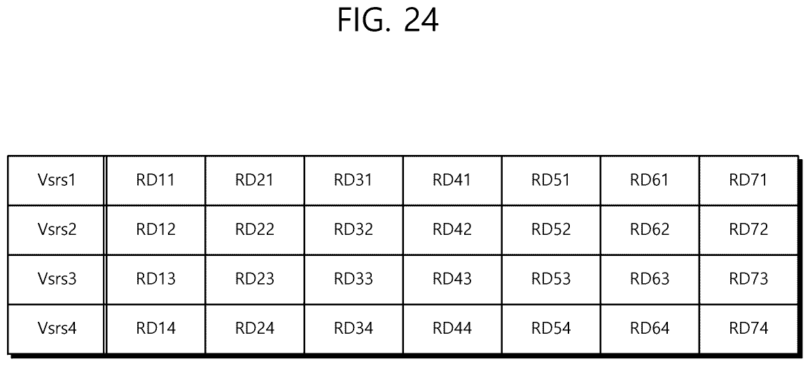

FIG. 24 a table illustrating sub-read voltage sets for a TLC, according to an embodiment. Referring to FIG. 24, four (4) sub-read voltage sets Vsrs1, Vsrs2, Vsrs3, and Vsrs4 may be sub-read voltage sets for a TLC in which the number of types of coupling patterns is four (4). Each of the four (4) sub-read voltage sets Vsrs1, Vsrs2, Vsrs3, and Vsrs4 may include seven (7) sub-read voltages RD11 to RD71, RD12 to RD72, RD13 to RD73, or RD14 to RD74.

The four (4) sub-read voltage sets Vsrs1, Vsrs2, Vsrs3, and Vsrs4 may be stored in the memory controller 1200 as a data structure of the read voltage set table 1230 of FIG. 1, for example.

Although the sub-read voltage sets for the TLC are shown in FIG. 24 as having seven (7) sub-read voltages, the present disclosure is not limited in this regard. For example, each sub-read voltage set for a single-level cell (SLC) may include two (2) sub-read voltages, each sub-read voltage set for a multi-level cell (MLC) may include four (4) sub-read voltages, and each sub-read voltage set for a QLC may include 16 sub-read voltages.

Moreover, although FIG. 24 shows a case in which the number of types of sub-read voltage sets for the TLC is four (4), the present disclosure is not limited in this regard, and the number of types of sub-read voltage sets may be equal to the number of types of coupling patterns.

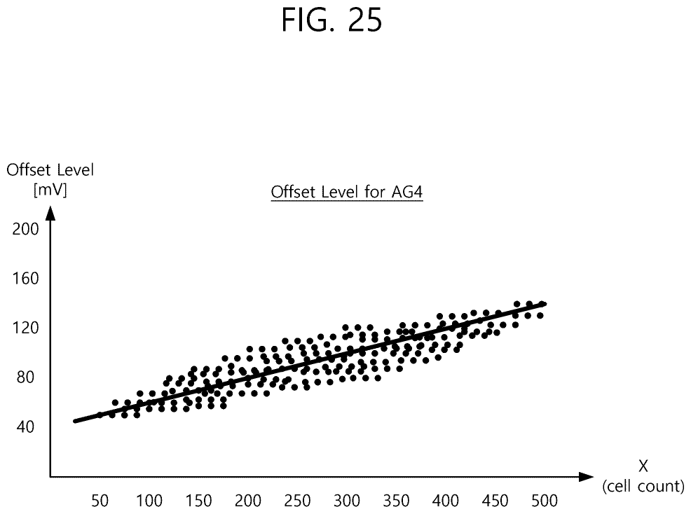

FIG. 25 is a graph illustrating the results of measuring the correlation between the cell count value of a specific area X of the distribution and the offset level. In the graph of FIG. 25, an abscissa denotes a cell count value of a specific area X of the distribution, and an ordinate denotes the offset level OL. FIG. 25 shows the offset levels of the fourth coupling pattern affected by the fourth aggressor cell group.

In an example case in which the cell count value is 50, the offset level is about 50 mV, and in an example case in which the cell count value is 100, the offset level is about 60 mV. In an example case in which the cell count value is 150, the offset level is about 70 mV, and in an example case in which the cell count value is 200, the offset level is about 80 mV. In an example case in which the cell count value is 250, the offset level is about 90 mV, and in an example case in which the cell count value is 300, the offset level is about 100 mV. In an example case in which the cell count value is 350, the offset level is about 110 mV, and in an example case in which the cell count value is 400, the offset level is about 120 mV. In an example case in which the cell count value is 450, the offset level is about 130 mV, and in an example case in which the cell count value is 500, the offset level is about 140 mV.

In addition to the fourth aggressor cell group, the first to third coupling patterns affected by the first to third aggressor cell groups may also experimentally obtain offset levels.

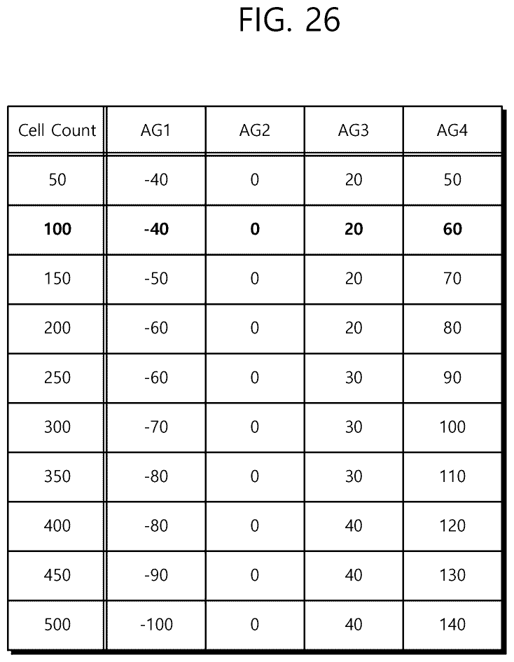

FIG. 26 is a table illustrating an example embodiment of cell count values and offset levels of the first to fourth aggressor cell groups.

Referring to FIG. 1 and FIG. 26, table data may be managed by a memory controller 1200. For example, the memory controller 1200 may include a read managing unit 1210, an ECC circuit 1220, and a read level set table 1230. The read managing unit 1210 may manage a plurality of read voltage levels. The ECC circuit 1220 may detect and correct errors in data read from the memory device 1100. The read level set table 1230 may be controlled by the read managing unit 1210 and may store information about cell count values and offset levels corrected by the ECC circuit 1220. The memory controller 1220 may calculate an offset level for a data recovery read operation using the table data stored in the read level set table 1230.

In an example case in which the cell count value of a specific area X of the distribution is 50, the offset level OL of the first coupling pattern corresponding to the first aggressor cell group AG1 is −40 mV. The offset level OL of the second coupling pattern corresponding to the second aggressor cell group AG2 may be 0 mV, the offset level OL of the third coupling pattern corresponding to the third aggressor cell group AG3 may be 20 mV, and the offset level OL of the fourth coupling pattern corresponding to the fourth aggressor cell group AG4 may be 50 mV.

In an example case in which the cell count value of a specific area X of the distribution is 100, the offset level OL of the first coupling pattern corresponding to the first aggressor cell group AG1 may be −40 mV, the offset level OL of the second coupling pattern corresponding to the second aggressor cell group AG2 may be 0 mV, the offset level OL of the third coupling pattern corresponding to the third aggressor cell group AG3 may be 20 mV, and the offset level OL of the fourth coupling pattern corresponding to the fourth aggressor cell group AG4 may be 60 mV. In this way, data on the offset level OL of each aggressor cell group according to the cell count value of a specific area X may be managed by the read level set table 1230.

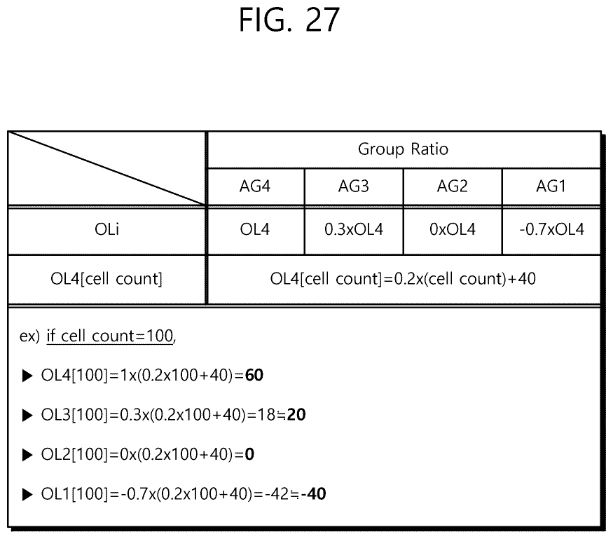

FIG. 27 is a table illustrating an example embodiment of a method of mathematically calculating the offset level using the cell count values of the first to fourth aggressor cell groups. The mathematical formula shown in FIG. 27 may be managed by the memory controller 1200. The read managing unit 1210 of the memory controller 1200 may calculate an offset level for a data recovery read operation using a mathematical formula set based on table data stored in the read level set table 1230.

Referring to FIG. 27, the offset levels OL1, OL2, and OL3 of the first to third coupling patterns corresponding to the first to third aggressor cell groups AG1, AG2, and AG3 may be defined based on the offset level OL4 of the fourth coupling pattern corresponding to the fourth aggressor cell group AG4.

For example, the first offset level OL1 may be −0.7 times the fourth offset level OL4. The second offset level OL2 may be 0 times the fourth offset level OLA. And the third offset level OL3 may be 0.3 times the fourth offset level OL4. Assuming that the cell count value is 100, the fourth offset level OL4[100] may be about 60 mV, the third offset level OL3[100] may be about 20 mV, the second offset level OL2[100] may be about 0 mV, and the first offset level OL1[100] may be about −40 mV.

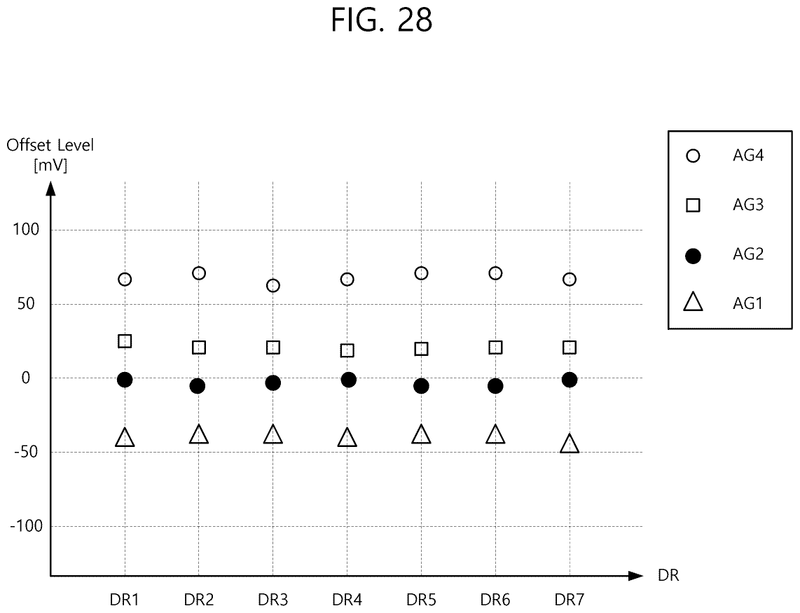

FIG. 28 is a graph illustrating offset levels for each state of selection memory cells that have been degraded by the first to fourth aggressor cell groups. In FIG. 28, an abscissa denotes voltage levels DR1 to DR7 of the data recovery read operation for each state, and an ordinate denotes the offset level OL.

The selection memory cells may exhibit a shift in program distribution due to the influence of aggressor cells and retention deterioration. FIG. 28 shows offset levels for each distribution by the first to fourth aggressor cell groups AG1, AG2, AG3, and AG4.

For example, at the first data recovery read voltage DR1, the selection memory cells having the first coupling pattern by the first aggressor cell group AG1 may have an offset level of about −40 mV. The selection memory cells having the second coupling pattern by the second aggressor cell group AG2 may have an offset level of about 0 mV. The selection memory cells having the third coupling pattern by the third aggressor cell group AG3 may have an offset level of about 20 mV. The selection memory cells having the fourth coupling pattern by the fourth aggressor cell group AG4 may have an offset level of about 50 mV.

At the second to seventh data recovery read voltages DR2 to DR7, the offset levels of the selection memory cells having the first to fourth coupling patterns by the first to fourth aggressor cell groups AG1 to AG4 may be almost the same. This means that it is not necessary to calculate all the offset levels for data recovery read operations for each state, and the off-cell level calculated in one state may be applied to other states.

The memory device 1100 according to the present disclosure may calculate the optimal read level for each state of the data recovery read operation using the cell count value of the specific area X. According to the present disclosure, since the number of data recovery read operations may be reduced, deterioration due to read disturbance may be reduced and the operation speed may be improved.

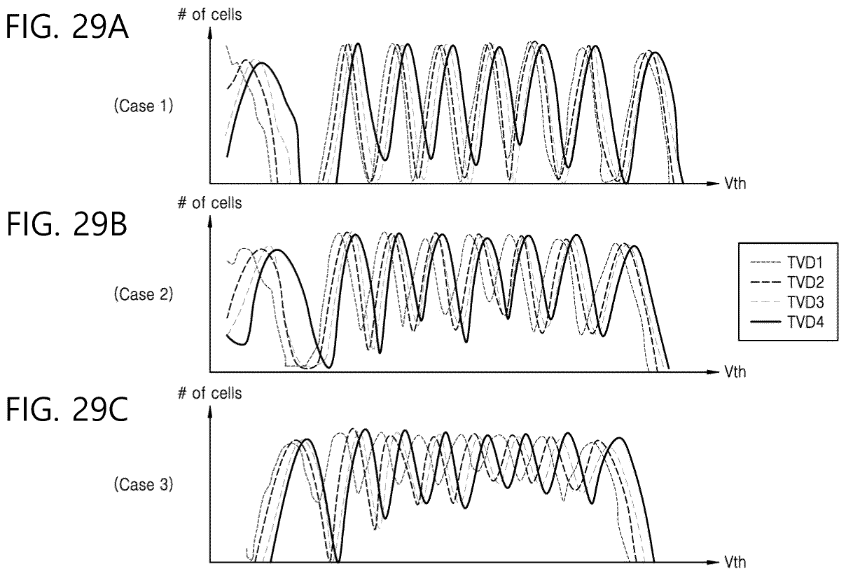

FIGS. 29A, 29B and 29C show graphs of threshold voltage distributions of selection memory cells coupled to adjacent word lines, according to an embodiment.

FIG. 29A illustrates a first example case (e.g., Case 1), which schematically shows first to fourth threshold voltage distributions TVD1, TVD2, TVD3, and TVD4 of a plurality of selection memory cells, according to the coupling effects of adjacent memory cells in an initial state of a memory device 1100. The number of threshold voltage distributions (e.g., TVD1, TVD2, TVD3, and TVD4) may be four (4), and the number of coupling patterns may be four (4).

The first threshold voltage distributions TVD1 may be, for example, threshold voltage distributions of a plurality of selection memory cells having a first coupling pattern CP1 from among the plurality of coupling patterns. The second threshold voltage distributions TVD2 may be, for example, threshold voltage distributions of a plurality of selection memory cells having a second coupling pattern CP2 from among the plurality of coupling patterns. The third threshold voltage distributions TVD3 may be, for example, threshold voltage distributions of a plurality of selection memory cells having a third coupling pattern CP3 from among the plurality of coupling patterns. The fourth threshold voltage distributions TVD4 may be, for example, threshold voltage distributions of a plurality of selection memory cells having a fourth coupling pattern CP4 from among the plurality of coupling patterns.

FIG. 29B illustrates a second example case (e.g., Case 2), which schematically shows the threshold voltage distributions TVD1, TVD2, TVD3, and TVD4 of the plurality of selection memory cells, according to the coupling effects of adjacent memory cells in a state of the memory device 1100, after a predetermined retention period. A degree to which the threshold voltage distributions TVD1, TVD2, TVD3, and TVD4 are distorted due to coupling between the adjacent memory cells in Case 2 may be greater than in Case 1. A degree to which the threshold voltage distributions TVD1, TVD2, TVD3, and TVD4 are widened and/or shifted in Case 2 may be greater than in Case 1.

FIG. 29C illustrates a third example case (e.g., Case 3), which corresponds to a case in which infrared radiation (IR) is irradiated during a process of the memory device 1100. A degree to which the threshold voltage distributions TVD1, TVD2, TVD3, and TVD4 are distorted due to coupling between the adjacent memory cells in Case 3 may be greater than in Case 1 and Case 2. A degree to which the threshold voltage distributions TVD1, TVD2, TVD3, and TVD4 are widened and/or shifted in Case 3 may be greater than in Case 1 and Case 2.

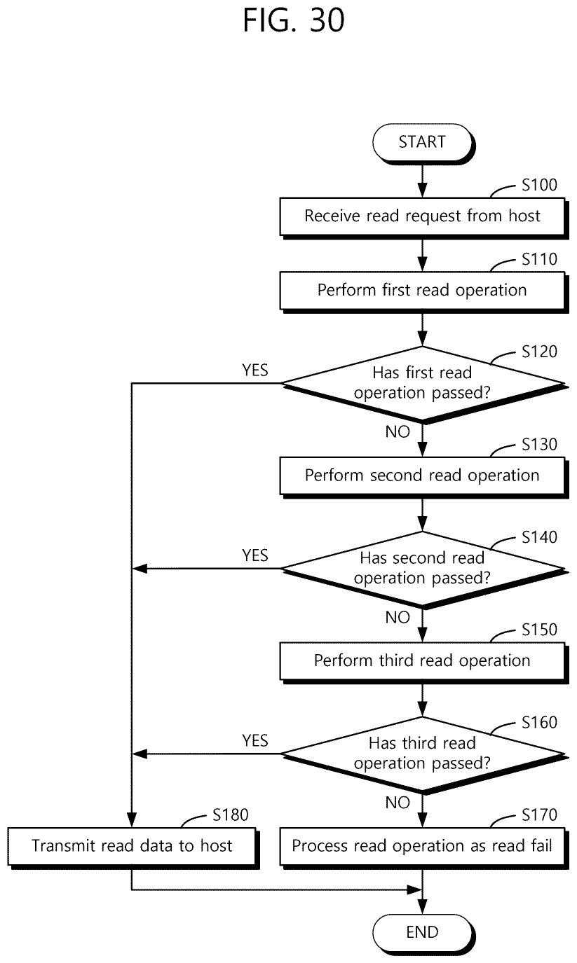

FIG. 30 is a flowchart for explaining a data read operation method of a storage device according to embodiments of the present disclosure. In operation S100, a storage device (see FIG. 1, 1000) may receive a read request from a host (see FIG. 1, 1500).

In operation S110, a memory controller (see FIG. 1, 1200) may perform a first read operation based on a read request provided from the host 1500. For example, the memory controller may perform the first read operation in response to the read request provided from the host 1500. The first read operation may be an operation of reading, by the memory device 1100, stored data based on a default read voltage set. The first read operation may be referred to as a normal read operation.

In operation S120, the memory controller 1200 may check whether the first read operation passes (e.g., the first read operation is successful). For example, the memory controller 1200 may determine whether or not the first read operation passes based on whether read data is normal data and/or data including an error that is correctable by the ECC circuit 1220. In an embodiment, the read managing unit 1210 may determine whether the first read operation has passed, according to whether an error in the read data is correctable by the ECC circuit 1220. In an example case in which the first read operation does not pass (NO), operation S130 may be performed, and in an example case in which the first read operation passes (YES), operation S180 may be performed.

In operation S130, the memory controller 1200 may perform a second read operation. The second read operation may be an operation of reading data based on a history read voltage set. The second read operation may be referred to as a history read operation.

In operation S140, the memory controller 1200 may check whether the second read operation has passed (e.g., the second read operation is successful). In an embodiment, the read managing unit 1210 may determine whether the second read operation has passed, according to whether an error in the read data is correctable by the ECC circuit 1220. In an example case in which the second read operation is not a pass (NO), operation S150 may be performed, and in an example case in which the second read operation is a pass (YES), operation S180 may be performed.

In operation S150, the memory controller 1200 may perform a third read operation. The third read operation may be an operation of reading data based on at least one sub-read voltage set by executing a recovery code. The third read operation may be referred to as a data recovery read operation.

In operation S160, the memory controller 1200 may check whether the third read operation has passed (e.g., the third read operation is successful). In an embodiment, the read managing unit 1210 may determine whether the third read operation has passed, according to whether an error in the read data is correctable by the ECC circuit 1220. In an example case in which the third read operation is not a pass (NO), operation S170 may be performed, and in an example case in which the third read operation is a pass (YES), operation S180 may be performed.

In operation S170, the memory controller 1200 may process the read operation as a read fail. In an example case in which the first read operation passes (S120, YES), the second read operation passes (S140, YES), or the third read operation passes (S160, YES), a operation of transmitting the read data to the host 1500 in operation S180 may be performed.

According to an embodiment, the data recovery read operation (e.g., the third read operation) may be performed by using an optimum read voltage, which may be calculated according to an aggressor cell group of adjacent memory cells. As a result, the probability of a read pass may be increased, and the performance and reliability of the storage device 1000 may be improved.

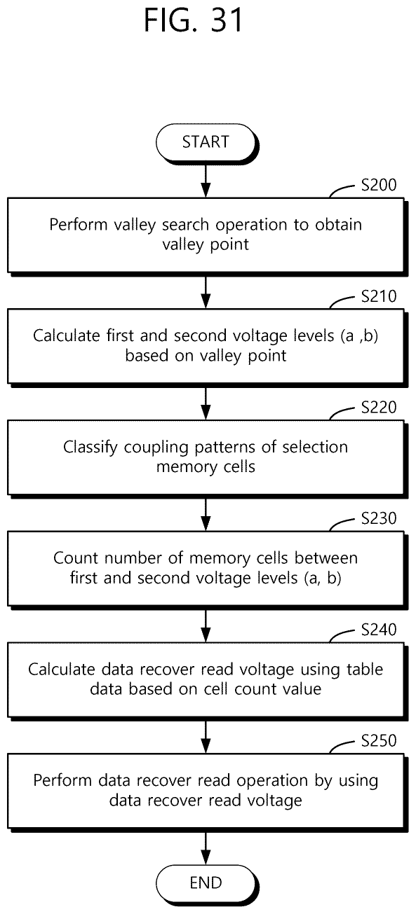

FIG. 31 is a flowchart of a data recovery read operation method, according to an embodiment. In operation S200, the memory controller 1200 may perform a valley search operation to obtain a valley point.

In operation S210, the memory controller 1200 may calculate a first voltage level (a) and a second voltage level (b) based on the valley point. For example, the first and second voltage levels (a, b) may be obtained as illustrated with reference to FIG. 23.

In operation S220, the memory controller 1200 may classify coupling patterns of selection memory cells according to aggressor cell groups of each of the adjacent memory cells. Operation S220 may include a grouping operation and a classifying operation.

In the grouping operation, the memory controller 1200 may group adjacent memory cells connected to at least one adjacent word line aWL physically adjacent to the selection word line sWL into a plurality of aggressor cell groups. In the classifying operation, the memory controller 1200 may classify selection memory cells into a plurality of coupling patterns according to each of the plurality of aggressor cell groups.

At least two or more group determination read voltages (e.g., Vgd1, Vgd2, Vgd3) may be applied to one adjacent word line aWL. Adjacent memory cells may be grouped into three or more aggressor cell groups, and selection memory cells may have coupling patterns corresponding to the aggressor cell groups.

In operation S230, the memory controller 1200 may count the number of memory cells in a specific area between the first and second voltage levels (see FIG. 23, a, b). The cell count value of the specific area may be obtained by calculating the number of off cells (or on cells) in “a” and “b”, and then using the difference between the off cells (or on cells) calculated in “a” and “b”.

In operation S240, the memory controller 1200 may calculate the offset level OL based on the cell count value. The memory controller 1200 may calculate the offset level OL using table data in the read level set table 1230. However, the disclosure is not limited thereto, and as such, according to another embodiment, the memory controller 1200 may also calculate the offset level OL using a mathematical formula or a mathematical algorithm. The memory controller 1200 may calculate the data recovery read voltage using table data or a mathematical formula, etc.

In operation S250, the memory controller 1200 may perform a data recovery read operation using the data recovery read voltage.

The memory controller 1200 may obtain the cell count value of a specific area (X) of the distribution once and use this value to find an offset level OL for the optimal data recovery read operation for each coupling pattern. Since the memory device 1100 may find the optimal offset level with a single read operation without performing multiple read operations, it may reduce deterioration due to read disturbance and improve the operation speed.

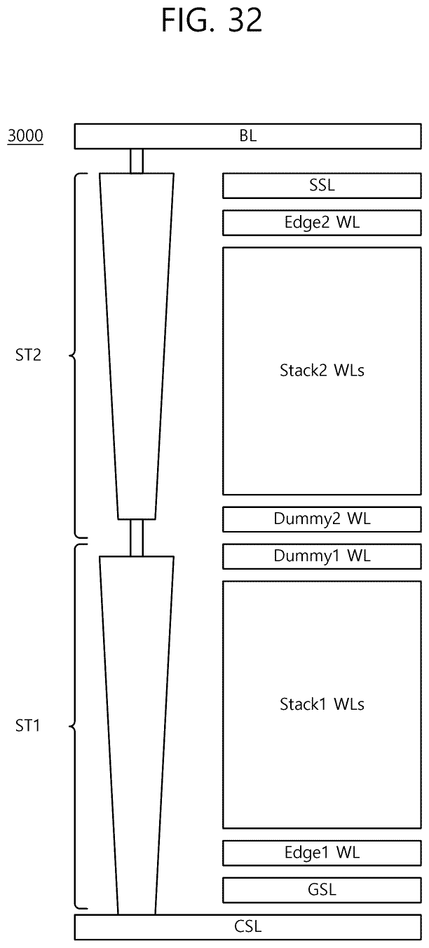

FIG. 32 is a diagram illustrating an example embodiment of a memory device having a multi-stack structure. Referring to FIG. 32, the memory device 3000 may have a first stack ST1 and a second stack ST2. However, the disclosure is not limited thereto, and as such, according to an embodiment, the memory device 3000 may have a multi-stack structure with more than two stacks. The first stack ST1 may be located at the bottom, and the second stack ST2 may be located at the top. For example, the second stack ST2 may be provided on the first stack ST1.

According to an embodiment, the first stack ST1 and the second stack ST2 may be bonded to form a pillar of the memory device 3000. A plurality of dummy word lines (e.g., Dummy1 WL and Dummy2 WL) may be included at junctions of the first and second stacks ST1 and ST2. The first stack ST1 may be positioned between the common source line CSL and the first dummy word line Dummy1 WL. The second stack ST2 may be positioned between the second dummy word line Dummy2 WL and the bit line BL.

The first stack ST1 may include a ground selection line GSL, a first edge word line Edge1 WL, and first stack word lines Stack1 WLs. The second stack ST2 may include second stack word lines Stack2 WLs, second edge word lines Edge2 WL and a string selection line SSL. Memory cells connected to the first and second edge word lines Edge1 WL and Edge2 WL may store bit data different from the other memory cells. For example, memory cells connected to the first and second edge word lines Edge1 WL and Edge2 WL may be SLC or MLC, and memory cells connected to the other word lines may be TLC or QLC.

The memory device 3000 may group adjacent memory cells connected to adjacent word lines adjacent to a selection word line into a plurality of aggressor cell groups during a data recovery read operation, and may classify coupling patterns of selection memory cells connected to the selection word line according to each aggressor cell group. The memory device 3000 may count the number of memory cells existing in a specific area of the first and second states neighboring one of the coupling patterns, and calculate an offset level for a data recovery read operation of the first and second states based on the number of counted memory cells.

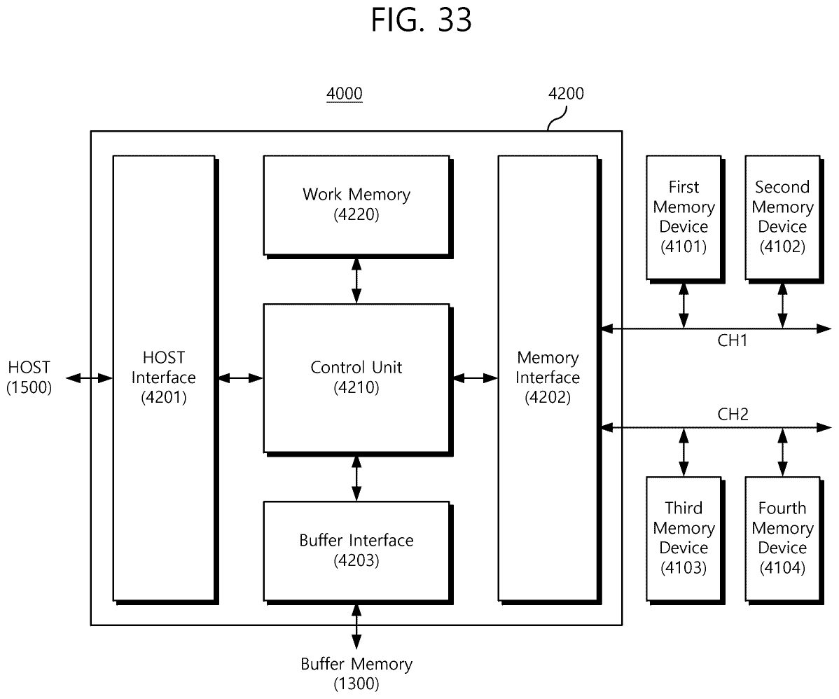

FIG. 33 is a block diagram illustrating an example in which a storage device according to an embodiment of the present disclosure is implemented with a solid state drive (SSD). Referring to FIG. 33, an SSD 4000 may include a plurality of memory devices (a first memory device 4101, a second memory device 4102, a third memory device 4103 and a fourth memory device 4104) and an SSD controller 4200.

The first and second memory devices 4101 and 4102 may be connected with the SSD controller 4200 through a first channel CH1. The third and fourth memory devices 4103 and 4104 may be connected with the SSD controller 4200 through a second channel CH2. The number of channels connected with the SSD controller 4200 may be 2 or more. The number of memory devices connected with one channel may be 2 or more.

The SSD controller 4200 may include a host interface 4201, a memory interface 4202, a buffer interface 4203, a control unit 4210, and a work memory 4220. The SSD controller 4200 may be connected with a host 1500 through the host interface 4201. Depending on a request of the host 1500, the SSD controller 4200 may write data in the corresponding memory device or may read data from the corresponding memory device.

The SSD controller 4200 may be connected with the plurality of memory devices 4101 to 4104 through the memory interface 4202 and may be connected with a buffer memory 1300 through the buffer interface 4203. The memory interface 4202 may provide data, which are temporarily stored in the buffer memory 1300, to the plurality of memory devices through the channels CH1 and CH2. The memory interface 4202 may transfer the data read from the plurality memory devices 4101 to 4104 to the buffer memory 1300.

The control unit 4210 may analyze and process the signal received from the host 1500. The control unit 4210 may control the host 1500 or the plurality memory devices 4101 to 4104 through the host interface 4201 or the memory interface 4202. The control unit 4210 may control operations of the plurality memory devices 4101 to 4104 by using firmware for driving the SSD 4000.

The SSD controller 4200 may manage data to be stored in the plurality of memory devices 4101 to 4104. In a sudden power-off event, the SSD controller 4200 may back up the data stored in the work memory 4220 or the buffer memory 1300 to the plurality of memory devices 4101 to 4104.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A memory device comprising:
a memory cell array comprising a plurality of memory cells connected to a plurality of word lines; and
a control logic configured to:
group adjacent memory cells, among the plurality of memory cells, connected to an adjacent word line adjacent to a selection word line, among the plurality of word lines, into a plurality of aggressor cell groups,
identify one or more coupling patterns of selection memory cells connected to the selection word line based on each of the plurality of aggressor cell groups,
count a number of first memory cells in a first area of neighboring first and second states corresponding to a first coupling pattern, among the one or more coupling patterns, and
obtain an offset level for a data recovery read operation of the first and second states based on the number of first memory cells.

2. The memory device of claim 1,
wherein the control logic is further configured to obtain a voltage level for the data recovery read operation of the first and second states based on the offset level.

3. The memory device of claim 2,
wherein the control logic is further configured to obtain the offset level for the data recovery read operation based on the number of first memory cells using data in a table.

4. The memory device of claim 2,
wherein the control logic is further configured to obtain the offset level for the data recovery read operation based on the number of first memory cells using a formula.

5. The memory device of claim 2,
wherein the control logic is further configured to obtain a voltage level for a data recovery read operation of a third state based on the voltage level for the data recovery read operation of the first and second states.

6. The memory device of claim 1,
wherein the control logic is further configured to obtain a number of memory cells in the first area by calculating a difference in off cells or on cells between first and second voltage levels corresponding to the first area.

7. The memory device of claim 6,
wherein the first and second voltage levels are predetermined or changed.

8. The memory device of claim 1,
wherein the first and second states are neighboring program states of the highest level.

9. The memory device of claim 1,
wherein the adjacent memory cells connected to the adjacent word line are programmed, and
wherein the selection memory cells connected to the selection word line are programmed after the adjacent memory cells are programmed.

10. The memory device of claim 1,
wherein the adjacent memory cells connected to the adjacent word line are closer to a substrate than the selection memory cells connected to the selection word line.

11. A storage device comprising:
a memory device comprising a memory cell array having a plurality of memory cells connected to a plurality of word lines, and a peripheral circuit configured to control the memory cell array; and
a memory controller configured to:
group adjacent memory cells, among the plurality of memory cells, connected to an adjacent word line adjacent to a selection word line, among the plurality of word lines into a plurality of aggressor cell groups,
identify one or more coupling patterns of selection memory cells connected to the selection word line based on each of the plurality of aggressor cell groups,
count a number of first memory cells in a first area of neighboring first and second states corresponding to a first coupling pattern, among the one or more coupling patterns, and
obtain an offset level for a data recovery read operation of the first and second states based on the number of first memory cells.

12. The storage device of claim 11,
wherein the memory controller is further configured to obtain a voltage level for the data recovery read operation of the first and second states using the offset level.

13. The storage device of claim 12,
wherein the memory controller comprises:
a read managing unit configured to manage a plurality of read voltage levels;
an ECC circuit configured to detect and correct errors in data read from the memory device; and
a read level set table configured to store data comprising information regarding a cell count value corrected by the ECC circuit and the offset level,
wherein the memory controller is further configured to obtain the offset level for the data recovery read operation of the first and second states using data stored in the read level set table.

14. The storage device of claim 13,
wherein the read managing unit is further configured to obtain the offset level for the data recovery read operation of the first and second states using a mathematical formula set based on the data stored in the read level set table.

15. The storage device of claim 13,
wherein the read managing unit is further configured to obtain a voltage level for a data recovery read operation of a third state based on the voltage level for the data recovery read operation of the first and second states.

16. The storage device of claim 11,
wherein the memory device is a flash memory having a three-dimensional structure in which memory cells are vertically stacked from a substrate.

17. The storage device of claim 16,
wherein the memory device is a storage device in which an upper chip comprising the memory cell array and a lower chip comprising the peripheral circuit are connected to each other in a bonding manner.

18. A data recovery read method of a storage device which includes a memory device having a plurality of memory cells connected to a plurality of word lines and a memory controller for controlling the memory device, the data recovery read method comprising:
grouping adjacent memory cells, among the plurality of memory cells, connected to an adjacent word line adjacent to a selection word line, among the plurality of word lines, into a plurality of aggressor cell groups;
identifying one or more coupling patterns of selection memory cells connected to the selection word line based on each of the plurality of aggressor cell groups;
counting a number of first memory cells in a first area of neighboring first and second states corresponding to a first coupling pattern, among the one or more coupling patterns; and
obtaining an offset level for a data recovery read operation of the first and second states based on the number of first memory cells.

19. The method of claim 18, further comprising:
obtaining a voltage level for the data recovery read operation of the first and second states based on the offset level, and
wherein the offset level for the data recovery read operation is obtained based on the number of first memory cells using data in a table or using a formula.

20. The method of claim 18, further comprising:
obtaining a voltage level for a data recovery read operation of a third state based on the voltage level for the data recovery read operation of the first and second states.
